(19) United States
(12) Patent Application Publication
(10) Pub. No.: US 2013/0102159 A1
(43) Pub. Date: Apr. 25, 2013

(54) SUBSTRATE PROCESSING APPARATUS, SUBSTRATE TRANSFER METHOD AND METHOD FOR MANUFACTURING SEMICONDUCTOR DEVICE

(71) Applicant: HITACHI KOKUSAI ELECTRIC INC., Tokyo (JP)

(72) Inventors: Hiroshi KOTANI, Toyama-shi (JP); Tsukasa IIDA, Tonami-shi (JP); Yasuhiro MIZUGUCHI, Toyama-shi (JP); Takeo SATO, Toyama-shi (JP); Yoshihiko NAKAGAWA, Toyama-shi (JP); Risa HOSOKAWA, Imizu-shi (JP)

(73) Assignee: HITACHI KOKUSAI ELECTRIC INC., Tokyo (JP)

(21) Appl. No.: 13/632,685

(22) Filed: Oct. 1, 2012

(30) Foreign Application Priority Data
Oct. 19, 2011 (JP) 2011-230111
Jul. 13, 2012 (JP) 2012-157479

(51) Int. Cl. H01L 21/677; C23C 16/52; H01L 21/306; H01L 21/02

(52) U.S. Cl. 438/758; 118/715; 118/712; 156/345.24; 414/806; 257/E21.002

(57) ABSTRACT

To provide a substrate processing apparatus, including: a plurality of process chambers in which a prescribed number of each type of substrates is processed; and a controller configured to decide the number of dummy substrates so that the number of the dummy substrates used in each process chamber is approximately the same between the process chambers, when the number of the dummy substrates used in each process chamber is decided so that the number of each type of substrates used in each process chamber reaches the prescribed number.

### TECHNICAL FIELD

The present invention relates to a substrate processing apparatus including a process chamber for processing a plurality of substrates, and a substrate transfer method and a method for manufacturing a semiconductor device.

### DESCRIPTION OF RELATED ART

In a substrate processing apparatus including a process chamber for processing substrates such as semiconductor substrates (semiconductor wafers), a general operation method of using dummy substrates is as follows. Namely, a substrate storage unit in which a plurality of dummy substrates are held, is set to be resident in the substrate processing apparatus, and when product substrates do not satisfy the number of substrates that can be processed in the process chamber, deficient number of dummy substrates are unloaded from the substrate storage unit, and a combination (called batch hereafter) of the substrates that can be processed at once in the process chamber is constituted. The dummy substrate that has undergone substrate processing, is returned to an inside of the substrate storage unit and is repeatedly used. For example, according to patent document 1, a vacant space of a substrate placing table which is generated in a last portion of a lot, is embedded with the dummy substrate, thus contributing to improvement of a processing quality in the process chamber.

Further, since the dummy substrate is repeatedly used, deposited films are accumulated on the dummy substrate in a process of using the dummy substrate multiple numbers of times. Therefore, in order to prevent a peel-off of the film and dust due to increase of a cumulative film thickness and a warpage and a deformation of the dummy substrate by a stress of the deposited films, the dummy substrate is exchanged when the frequency of use of the dummy substrate exceeds a prescribed value, or when cumulative film thickness value exceeds a prescribed film thickness value. In a production line of a plant, when any one of the plurality of dummy substrates has a value exceeding the aforementioned prescribed values, the dummy substrate is exchanged together with the substrate storage unit, and is equally disposed or reproduced. Therefore, the dummy substrate is selected based on the cumulative film thickness value of the dummy substrates, to thereby achieve an effective utilization of all dummy substrates (for example see patent document 2).
Patent document 1: Patent Publication No. 3824835
Patent document 2: Patent Publication No. 4294972

When operating a conventional dummy substrate, it is preferable that the dummy substrate is separately used in each process chamber, to suppress a cross contamination across the process chambers. However, for example a deviation is generated in uses of the dummy substrate when contents of the substrate processing is different in each process chamber, and even in a case of the dummy substrate with a small cumulative film thickness value, the dummy substrate is exchanged and disposed together with the dummy substrate that should be exchanged.

Thus, the deviation in frequency of use and sheet number of the dummy substrates, causes a low use efficiency in the whole dummy substrates. Therefore, as a result of strenuous efforts by inventors of the present invention regarding a distribution of the dummy substrates to each process chamber, ranking of the process chamber in which the dummy substrates are preferentially used or ranking of the used dummy substrates, and a technique of a batch assembly for each group classified by the contents of the substrate processing, the present invention is achieved. Wherein, assembly of the batch is called the batch assembly.

### SUMMARY OF THE INVENTION

An object of the present invention is to provide a substrate processing apparatus, a substrate transfer method and a method for manufacturing a semiconductor device, capable of improving a use efficiency of dummy substrates and suppressing an increase of a frequency of exchange of the dummy substrates.

According to an aspect of the present invention, there is provided a substrate processing apparatus, including:

a plurality of process chambers in which a prescribed number of each type of substrates is processed; and

a controller configured to decide the number of dummy substrates so that the number of the dummy substrates used in each process chamber is approximately the same between the process chambers, when the number of the dummy substrates used in each process chamber is decided so that the number of each type of substrates used in each process chamber reaches the prescribed number.

According to other aspect of the present invention, there is provided a substrate transfer method, including:

deciding the number of dummy substrates used in each process chamber, so that the number of each type of substrates in each process chamber reaches a prescribed number; and

transferring each type of the substrates,

when deciding the number of the dummy substrates, the number of the dummy substrates is decided so that the number of the dummy substrates used in each process chamber is approximately the same in each process chamber.

According to further other aspect of the present invention, there is provided a method for manufacturing a semiconductor device, including:

deciding the number of dummy substrates used in each process chamber, so that the number of each type of substrates in each process chamber reaches a prescribed number;

transferring each type of the substrates; and

processing each type of the substrates in each process chamber,

when deciding the number of the dummy substrates, the number of the dummy substrates is decided so that the number of the dummy substrates used in each process chamber is approximately the same in each process chamber.

According to further other aspect of the present invention, there is provided a substrate processing apparatus, comprising:

a plurality of process chambers in which a prescribed number of each type of substrates are processed; and

a controller configured to decide the number of dummy substrates used in each process chamber so that the number of each type of the substrates reaches the prescribed number in each process chamber,

when each type of the substrates is distributed to each process chamber and multiple numbers of times of processing are applied to each type of the substrates, the controller is configured to perform control to compare film thickness values of a deposited film on the dummy substrates in each process chamber in at least previous processing, and transfer the dummy substrates into the process chamber in which a film thickness value is small.

According to the present invention, improvement of a use efficiency of the dummy substrates and effective use of the dummy substrates are achieved, and a deviation in the frequency of use and sheet number of the dummy substrates in process chambers, can be suppressed.

### BRIEF DESCRIPTION OF THE DRAWINGS

FIG. 1 is a schematic block diagram of a substrate processing apparatus according to an embodiment of the present invention.

FIG. 2 is a class relation view of a relation between a recipe and a job for managing substrate processing according to an embodiment of the present invention.

FIG. 3 is an object relation view of a relation between a recipe and a job for distribution processing according to an embodiment of the present invention.

FIG. 4 is an object relation view of a relation between a recipe and a job for parallel processing according to an embodiment of the present invention.

FIG. 5 is an explanatory view of an example of a job generation by a controller according to an embodiment of the present invention.

FIG. 6 is a block diagram of the controller of the substrate processing apparatus according to an embodiment of the present invention.

FIG. 7 shows an example of a display screen of a displayer possessed by the substrate processing apparatus according to an embodiment of the present invention.

FIG. 8 is a class relation view of a relation of a main class on software executed by the controller according to an embodiment of the present invention.

FIG. 9 is a functional block diagram of the software executed by the controller of the substrate processing apparatus according to an embodiment of the present invention.

FIG. 10 is a flowchart of an outline of substrate processing steps in the substrate processing apparatus according to an embodiment of the present invention.

FIG. 11 is a flowchart of a carrier cassette reception processing by a material management unit executed by the controller according to an embodiment of the present invention.

FIG. 12 is a flowchart of a job generation processing by a job controller and a job grouping processing by a group controller executed by the controller according to an embodiment of the present invention.

FIG. 13 is a flowchart of a batch start request processing by the group controller executed by the controller according to an embodiment of the present invention.

FIG. 14 is a flowchart of currently execution group decision processing by the group controller executed by the controller according to an embodiment of the present invention.

FIG. 15 is a flowchart of a batch assembly processing by a batch assembly unit executed by the controller according to an embodiment of the present invention.

FIG. 16 is a flowchart of a former half of a substrate number decision processing by a batch assembly unit executed by the controller according to an embodiment of the present invention.

FIG. 17 is a view of a latter half of the substrate number decision processing by the batch assembly unit executed by the controller according to an embodiment of the present invention, and a flowchart using algorithm A1.

FIG. 18 is a view of the latter half of the substrate number decision processing by the batch assembly unit executed by the controller according to an embodiment of the present invention, and is a flowchart using algorithm A2.

FIG. 19 is a view of the latter half of the substrate number decision processing by the batch assembly unit executed by the controller according to an embodiment of the present invention, and is a flowchart using algorithm A3.

FIG. 20 is a flowchart of a dummy preferential use PM order decision processing by the batch assembly unit executed by the controller according to an embodiment of the present invention.

FIG. 21 is a flowchart of a batch charge processing by a group controller executed by the controller according to an embodiment of the present invention.

FIG. 22 is a flowchart of a PM status update processing by a PM managing unit and a dummy substrate status update processing by a material managing unit executed by the controller according to an embodiment of the present invention.

FIG. 23 is an explanatory view of a result of an intra-lot processing based on a different sequence recipe in the substrate processing apparatus according to examples 1, 2 of the present invention and comparative example 1.

FIG. 24 is an explanatory view of results of a plurality of lot processing based on the different sequence recipe in the substrate processing apparatus according to example 3 of the present invention and comparative example 2.

FIG. 25 is an explanatory view of results of a plurality of lot processing based on the same sequence recipe in the substrate processing apparatus according to example 3 of the present invention and comparative example 2.

FIG. 26 is a view of an example of a screen for selecting a system command, in the substrate processing apparatus according to other example of the present invention.

FIG. 27 is an explanatory view of an example of a screen for selecting a process chamber PM into which a product substrate is charged first when starting a lot, in the substrate processing apparatus according to other example of the present invention.

FIG. 28 shows a screen of an example of a result of data processing in the substrate processing apparatus according to other example of the present invention.

FIG. 29 is a view of a functional structure realized by a controller 239 in the substrate processing apparatus according to other example of the present invention.

FIG. 30 is a view of an example for more specifically describing other example of the present invention.

### DETAILED DESCRIPTION OF THE INVENTION

### An Embodiment of the Present Invention

An embodiment of the present invention will be described hereafter.

### (1) Structure of a Substrate Processing Apparatus

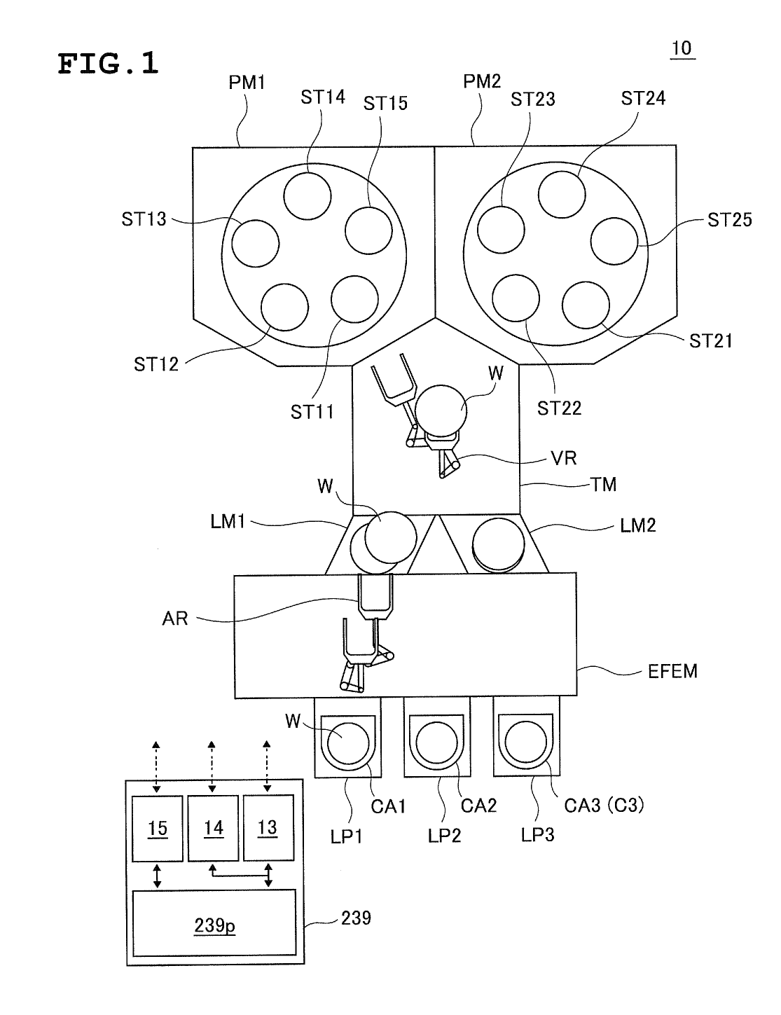

First, a structure of a substrate processing apparatus according to an embodiment of the present invention will be described, with reference to FIG. 1. FIG. 1 is a schematic block diagram of a multiple wafer-processing substrate processing apparatus 10 according to this embodiment.

As shown in FIG. 1, the substrate processing apparatus is divided to a vacuum side and an atmosphere side.

### (Structure of the Vacuum Side)

A vacuum sealed transfer chamber TM (Transfer Module), load lock chambers LM1 LM2, being spare chambers (Load Lock Module), are provided at the vacuum side of the substrate processing apparatus. The load lock chambers LM1, LM2, and the process chambers PM1, PM2 are disposed so as to surround an outer periphery of the vacuum transfer chamber TM.

The vacuum transfer chamber TM is configured to withstand a pressure (negative pressure) of less than an atmospheric pressure like a vacuum condition. In this embodiment, a casing of the vacuum transfer chamber TM is formed into a pentagon in planar view, with upper and lower both ends closed in a box shape.

A vacuum robot VR being a transfer unit, is provided in the vacuum transfer chamber TM. The vacuum robot VR transfers substrates W such as product substrates and dummy substrates made of silicon (Si), etc., between the load lock chambers LM1, LM2 and the process chambers PM1, PM2, by placing these substrates on two arms being a substrate placement part. Note that the vacuum robot VR is configured to perform elevating/descending operation while maintaining a sealing property of the vacuum transfer chamber TM. Further, the two arms are configured to be stretched in a horizontal direction, and also configured to perform rotary movement in a horizontal plane. Further, a substrate presence/absence sensor not shown is installed at a position in front of the load lock chambers LM1, LM2, and the process chambers PM1, PM2, so that a presence of the substrates W on the arm can be detected.

The process chambers PM1, PM2 include substrate placing tables ST11 to ST15 and ST 21 to ST25 on which the substrates W are placed, and are configured as multiple wafer-processing cambers for collectively processing five substrates W at once. Namely, the process chambers PM1, PM2 function as process chambers for adding a further value to the substrates W respectively, such as etching and ashing using plasma, etc., or a film deposition by a chemical reaction (CVD: Chemical Vapor Deposition) for example.

Further, the process chambers PM1, PM2 have each kind of structures according to its function, such as an introduction/exhaust mechanism and a temperature control/plasma discharge mechanism (not shown). These mechanisms include a mass flow controller not shown for controlling a flow rate of a process gas supplied into the process chambers PM2, PM2, a pressure controller 15 such as an automatic pressure controller (APC) for controlling a pressure in the process chambers PM2, PM2, a temperature adjuster not shown for controlling a temperature in the process chambers PM2, PM2, a valve digital I/O13 for controlling on/off of a valve for supplying and exhausting the process gas. Each of the aforementioned structures is electrically connected to a process chamber controller 239p. The structure of a control part 239 being a controller including the process chamber controller 239p will be described later.

Further, the process chambers PM1, PM2 are communicated with the vacuum transfer chamber TM through a gate valve not shown. Accordingly, the substrates W can be transferred between the process chambers PM1, PM2, and the vacuum transfer chamber TM, by opening the gate valve. Moreover, each kind of substrate processing can be performed to the substrate W while maintaining the pressure and a process gas atmosphere in the process chamber PM1, PM2, by closing the gate valve.

The load lock chambers LM2, LM2 function as spare chambers for loading the substrates W into the vacuum transfer camber TM, or function as a spare chamber for unloading the substrates W from an inside of the vacuum transfer chamber TM. A buffer stage not shown being the substrate placing part for temporarily supporting the substrates W during loading/unloading the substrates W, is provided respectively inside of the load lock chambers LM1, M2. The buffer stage may be configured as a multistage type slot for holding a plurality of (two for example) substrates W.

Further, the load lock chambers LM1, LM2 are communicated with the vacuum transfer chamber TM through the gate valve not shown, and are also communicated with an atmosphere transfer chamber EFEM as will be described later through the gate valve not shown. Accordingly, by opening the gate valve at the atmosphere transfer chamber EFEM side while closing the gate valve at the vacuum transfer chamber TM side, the substrates W can be transferred between the load lock chambers LM1, LM2, and the atmosphere transfer chamber EFEM while maintaining a vacuum sealed state in the vacuum transfer chamber TM.

Further, the load lock chambers LM2, LM2 are configured to withstand the negative pressure of less than the atmospheric pressure like a vacuum state, so as to vacuum-exhaust the inside of the chambers respectively. Accordingly, by opening the gate valve at the vacuum transfer chamber TM side after vacuum-exhausting the inside of the load lock chambers LM1, LM2 by closing the gate valve at the atmosphere transfer chamber EFEM side, the substrates W can be transferred between the load lock chambers LM1, LM2 and the vacuum transfer chamber TM, while maintaining the vacuum state inside of the vacuum transfer chamber T.

### (Structure of the Atmosphere Side)

Meanwhile, as described above, the atmosphere transfer chamber EFEM (Equipment Front End Module) being front modules connected to the load lock chambers LM1, LM2, and load ports LP1 to LP3 being substrate storage parts connected to the atmosphere transfer chamber EFEM, on which carrier cassettes CA1 to CA3 are placed as substrate storage units storing twenty-five substrates W per 1 lot, are provided at the atmosphere side of the substrate processing apparatus 10.

For example one set of atmosphere robot AR being the transfer unit, is provided inside of the atmosphere transfer chamber EFEM. The atmosphere robot AR transfers the substrates W mutually between the load rock chambers LM1, LM2, and the load ports LP1 to LP3. The atmosphere robot AR also has two arms being the substrate placing parts in the same way as the vacuum robot VR. Further, the substrate presence/absence sensor not shown is installed at a position in front of the load lock chambers LM1, LM2 inside of the atmosphere transfer chamber EFEM, so that the presence of the substrates W on the arm can be detected.

In addition, an orientation flat aligner not shown is provided inside of the atmosphere transfer chamber EFEM for aligning a crystal orientation of the substrates W. When each substrate W is a notch type, a notch aligner can also be provided as a substrate position correcting device. Further, a clean air unit not shown is provided in the atmosphere transfer chamber EFEM for supplying clean air into the atmosphere transfer chamber EFEM.

Each of the load ports LP1 to LP3 is configured to place each of the carrier cassettes CA1 to CA3 being substrate storage units for storing a plurality of substrates W, on each of the load ports LP1 to LP3. Slots (not shown) being storage parts for storing each substrate W, for example twenty-five slots in each one lot are provided in the carrier cassettes CA1 to CA3. When carrier cassettes CA1 to CA3 are placed, each of the load ports LP1 to LP3 is given to the carrier cassettes CA1 to CA3, so as to read and store barcodes etc., indicating a carrier ID for identifying the carrier cassettes CA1 to CA3.

Further, carrier cassette C3 in which the substrates W being the dummy substrates are stored, is resident in the load port LP3 for example, out of the load ports LP1 to LP3. The substrates W being the product substrates are stored in the carrier cassette CA1 or the carrier cassette CA2 for example, and is placed on the load port LP1 or the load port LP2, and is transferred into the substrate processing apparatus 10, to receive each kind of substrate processing. Note that in order to improve a substrate processing ability of the substrate processing apparatus 10, and in order to secure much transfer space for transferring the product substrates, the number of the carrier cassettes of the dummy substrate is preferably limited to one with a tendency of various types of products in small lots, wherein the carrier cassette is resident in the substrate processing apparatus.

The substrate processing apparatus 10 of this embodiment has been described above. Meanwhile, the number and the structure of the chambers and a combination of the chambers are not limited to the aforementioned case, and can be suitably selected.

### (2) Recipe and Job

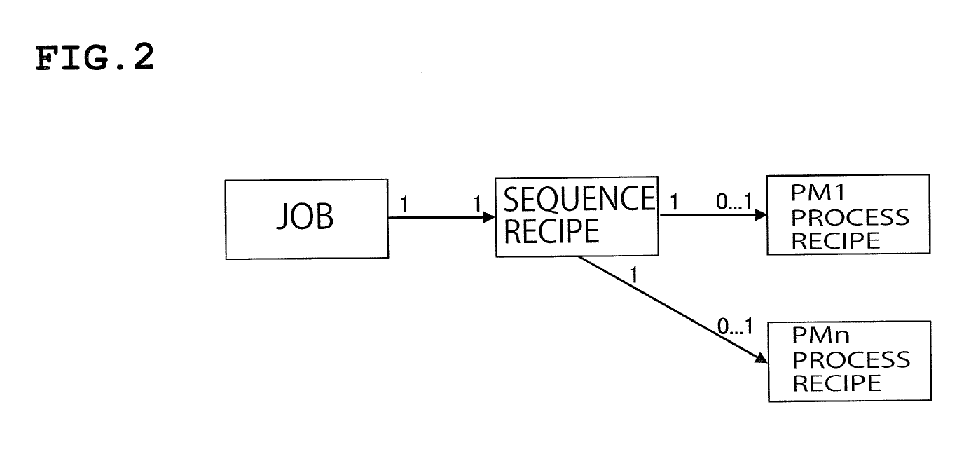

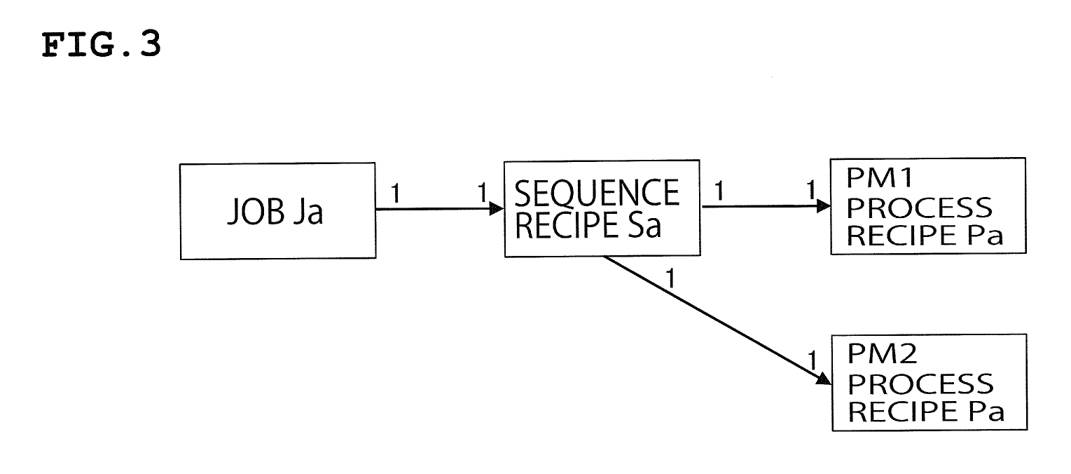

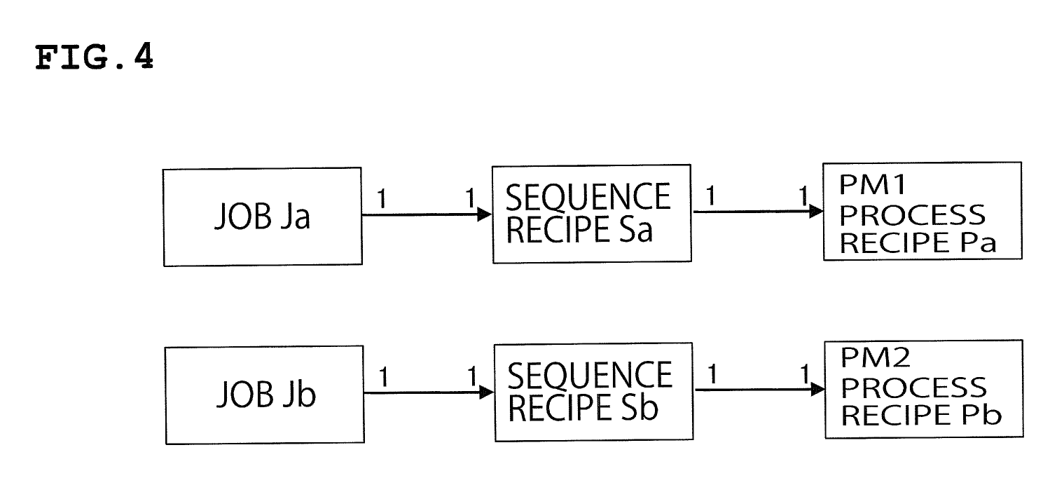

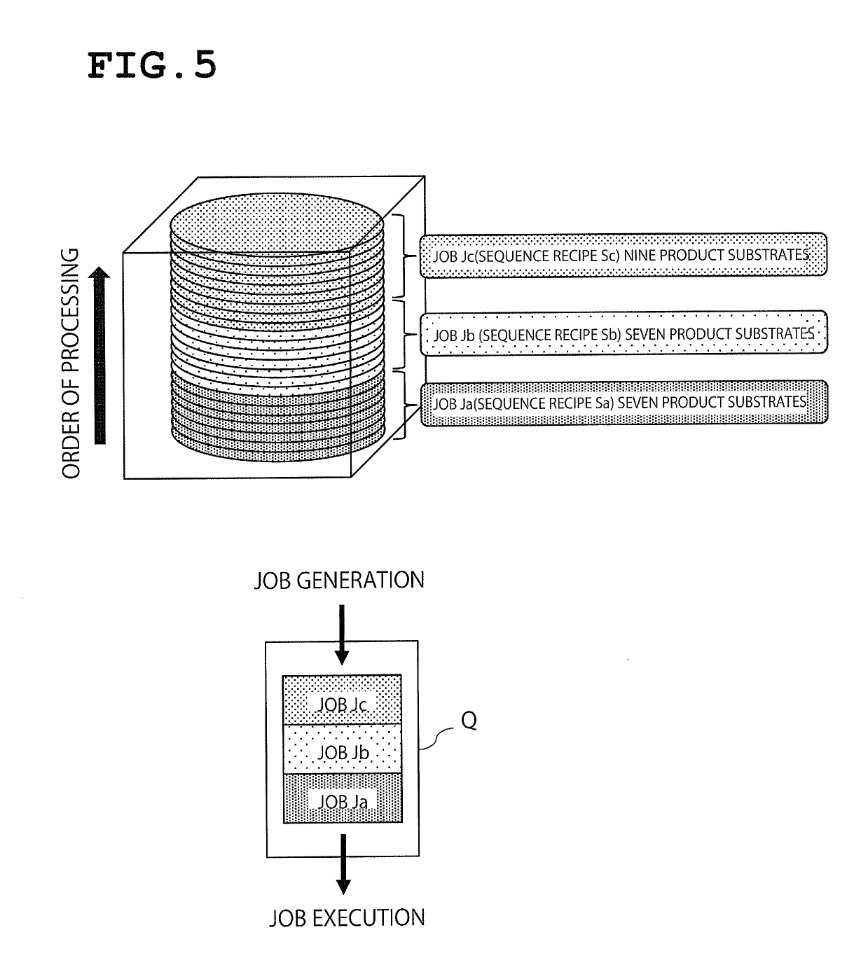

The substrate processing performed by the substrate processing apparatus 10 is managed by each kind of recipe and job. The recipe and the job will be described hereafter using FIG. 2 to FIG. 5. FIG. 2 is a class relation view of a relation between recipe and job for managing the substrate processing according to this embodiment. FIG. 3 is an object relation view showing a relation between recipe and job for a distribution processing according to this embodiment. FIG. 4 is an object relation view of a relation between recipe and job for performing a parallel processing according to this embodiment. FIG. 5 is an explanatory view of an example of generating a job by a control part 239 according to this embodiment.

As shown in FIG. 2, the recipe includes a process recipe of defining contents of the substrate processing in the process chambers PM1, PM2, and a sequence recipe of defining which process chamber is used to process the product substrates. The job is the object on the software executed by the control part 239, and is associated with the product substrates to be processed and the sequence recipe. For example, the job is generated under a request of processing the product substrates and is canceled by completion of the processing, every time the sequence recipe is different and every time the lot of the product substrates is different. A plurality of jobs can exist simultaneously, and can be executed in an order of generation. Note that the job is called a job object in some cases hereafter.

As shown in FIG. 2, the job has one sequence recipe. The sequence recipe has one or more process recipes, and has zero or one process recipe in each process chamber PM1, PM2 . . . PMn.

Next, explanation will be given for a case that the distribution processing and the parallel processing are performed in the substrate processing apparatus 10 including the aforementioned two process chambers PM1, PM2.

In a case that contents of the substrate processing is the same in both process chambers PM1 and PM2, and the product substrates may be processed in either of the process chambers PM1, PM2, the processing in this case is called the sorting process. In this case, as shown in FIG. 3, job Ja has a sequence recipe Sa, and the sequence recipe Sa has a process recipe Pa of the process chamber PM1, and a process recipe Pa of the process chamber PM2. When such a job Ja is executed, the substrate processing based on the process recipe Pa is applied to the product substrates which are associated with job Ja, in either the process chamber PM1 or the process chamber PM2.

The processing in a case of different contents of the substrate processing in the process chambers PM1, PM2 is called parallel processing. In this case, as shown in FIG. 4, different jobs Ja, Jb are generated and is simultaneously executed according to the content of each substrate processing. Namely, for example job Ja has the sequence recipe Sa, and the sequence recipe Sa has the process recipe Pa of the process chamber PM1. Further, for example job Jb has the sequence recipe Sb, and the sequence recipe Sb has the process recipe Pb of the process chamber PM2. Each job Ja, Jb can be simultaneously executed because the process chambers do not compete with each other. Therefore, the substrate processing based on the process recipe Pa in the process chamber PM1 is applied to the product substrates which are associated with the job Ja, and the substrate processing based on the process recipe Pb in the process chamber PM2 is applied to the product substrates which are associated with the job Jb, respectively simultaneously.

Note that in a single wafer processing substrate processing apparatus including three or more process chambers having only one substrate placing table, the distribution processing and the parallel processing are sometimes simultaneously executed. In this case, for example, the distribution processing based on the same process recipe is executed in two process chambers, and the parallel processing based on the process recipe different from the above recipe is executed in the other process chamber.

Next, an example of job generation and listing of jobs shown in FIG. 5 will be described.

As shown in FIG. 5, for example it is assumed that twenty-three product substrates are stored in the carrier cassette, and the job Ja having the sequence recipe Sa is distributed to seven product substrates, and the job Jb having the sequence recipe Sb is distributed to seven product substrates, and the job Jc having the sequence recipe Sc is distributed to the remained nine product substrates, out of twenty-three product substrates.

In this case, for example jobs Ja, Jb, and Jc are listed in an order of generation and are executed. First, the job Ja is generated and is listed in a job queue Q. Next, the job Jb is generated and is listed in the job queue Q. Finally, the job Jc is generated and is listed in the job queue Q. Each job Ja, Jb, Jc thus listed is executed sequentially from the job Ja being a head of the job queue Q. Generation and listing of each job is executed by the control part 239 as will be described later. Thus, the job queue Q in which a plurality of jobs are listed, is called a job list in some cases.

### (3) Structure of the Controller

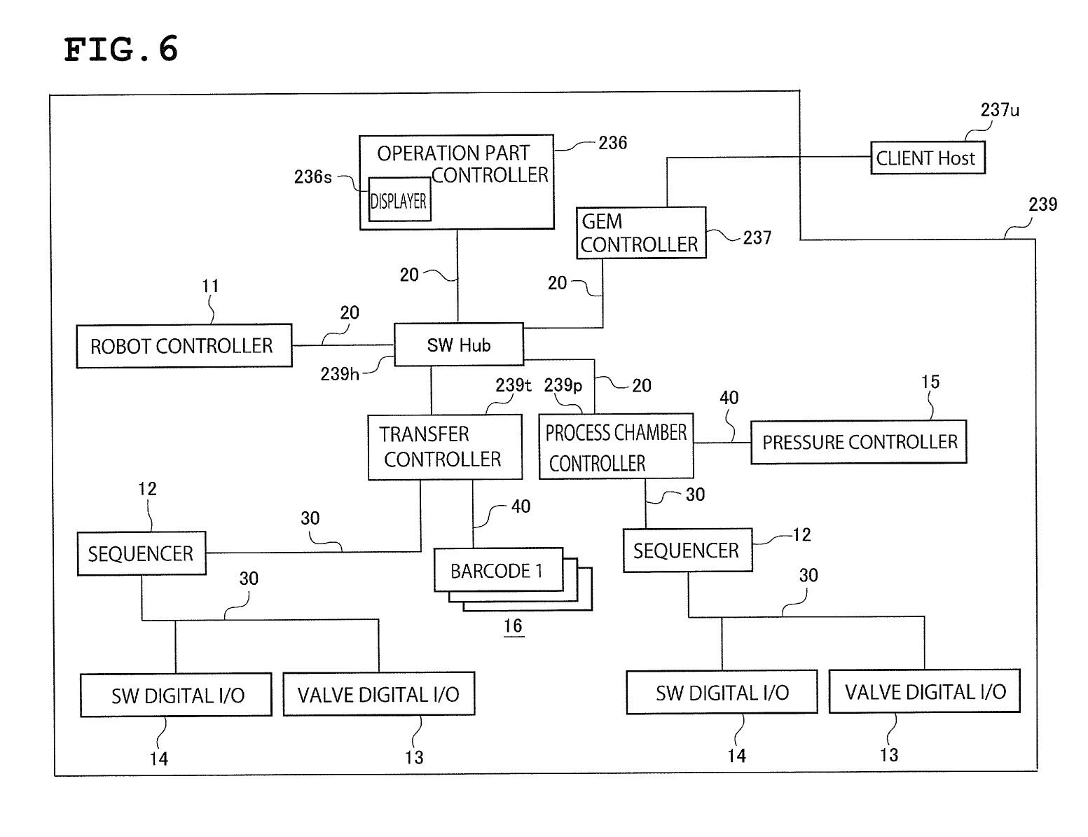

Next, the control part 239 being the controller for controlling the substrate processing apparatus 10, will be described using mainly FIG. 6. FIG. 6 is a block diagram of an example of a schematic structure of the control part 239 of the substrate processing apparatus 10.

As shown in FIG. 6, in the control part 239, an operation controller 236, a GEM controller 237, a transfer controller 239t, and a process chamber controller 239p are connected to each other by a communication network 20 such as LAN, through a switching hub 239h. Further, a robot controller 11 for controlling a vacuum robot VR provided in the vacuum transfer chamber TM and an atmosphere robot provided in the atmosphere transfer chamber EFEM, are provided by the communication network 20 such as LAN through the switching hub 239h.

The control part 239 being the controller is provided inside of the substrate processing apparatus 10, and is configured to control each part of the substrate processing apparatus 10 by providing a transfer controller 239t and a process chamber controller 239p. The transfer controller 239t and the process chamber controller 239p may be provided outside of the substrate processing apparatus 10 instead of being provided inside of the substrate processing apparatus 10.

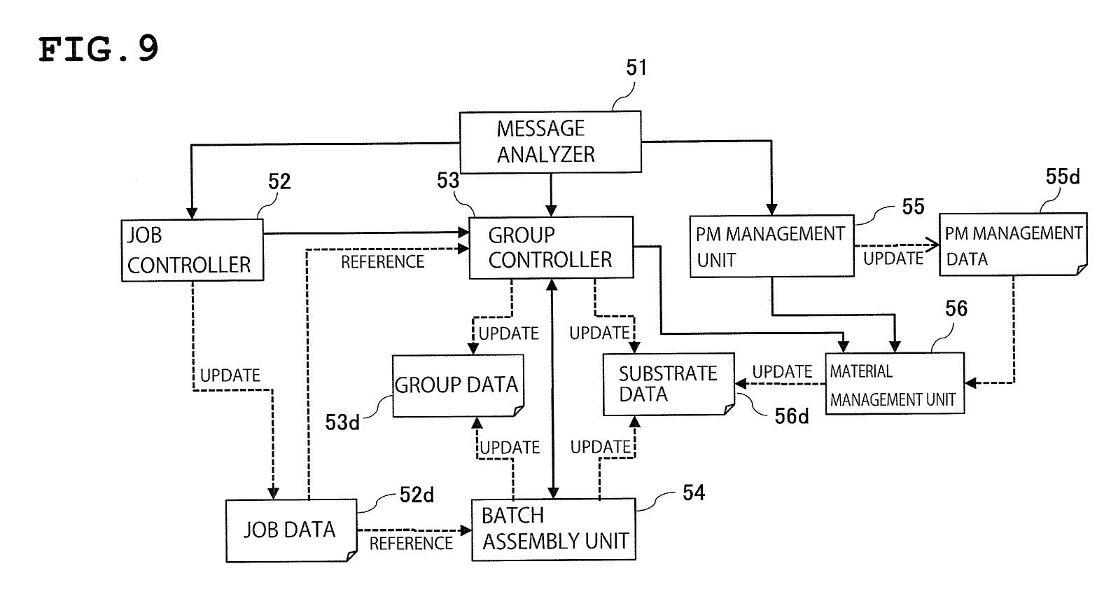

Further, the control part 239 has functions of a material management unit 56 that distributes the dummy substrate to each process chamber PM1, PM2, a group controller 53 that manages prescribed jobs having the same recipes as a group, and a batch assembly unit 54 that assembles a batch by combining the product substrate and the dummy substrate (see FIG. 9), and is configured to operate the dummy substrates and distribute the substrates W such as the dummy substrates and the product substrates. These functions of the control part 239 will be described later.

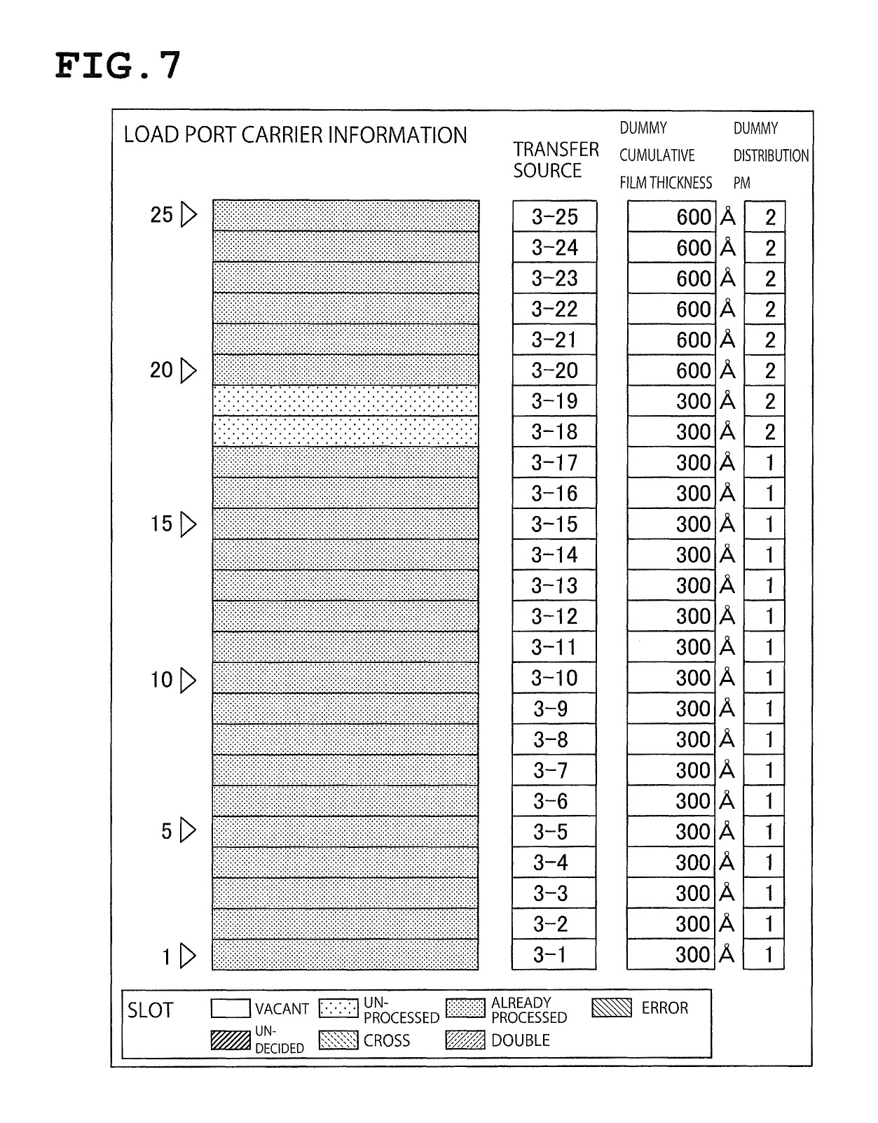

The operation part controller 236 is an interface with an operator, and is configured to receive an operation by the operator through a displayer 236s or an input device, etc., not shown. Further, in addition to a display of each slot, an distributed PM (process chamber) of the dummy substrate and information regarding a cumulative film thickness as will be described later, are displayed on the displayer 236s. FIG. 7 shows an example of a display screen of the displayer 236s.

FIG. 7 is a view of an example of load port carrier information of the load port LP3. As shown in FIG. 7, in this example, load source information, dummy cumulative film thickness values, and information regarding dummy distributed PM are displayed on the display screen, together with the display of each slot information. Each slot information is clearly shown so as to know the attribute of the dummy substrate placed on the slot. Explanatory notes are displayed at a lower side of the load port carrier information, and therefore by referring to the explanatory notes, a state of the dummy substrate placed on each slot can be grasped. For example, in a display example shown in FIG. 7, it is found that the dummy substrates placed on slots 18, 19 are unprocessed state, and the dummy substrates placed on other slots are processed state. Further, in loading source information 3-1, 3-2 . . . 3-25, 3 at a left side indicates LP3, and 1, 2 . . . 25 at a right side indicates slot numbers respectively. Dummy cumulative film thickness information is the information, becoming a threshold value for exchange. In this embodiment, 1(PM1) or 2(PM2) is indicated as the dummy distributed PM.

The GEM controller 237 is configured to be connected to a host computer 237u of a client, so as to realize an automated system in the plant.

The process chamber controller 239p and the transfer controller 239t are composed of CPU, etc., for example. Further, a valve digital I/O13 for controlling on/off of supplying and exhausting the process gas, and a SW digital I/O14 for controlling on/off of each kind of switch (SW), etc., are connected respectively to the process chamber controller 239p and the transfer controller 239t, through a sequencer 12.

Further, the pressure controller 15 such as an automatic pressure controller (APC) for controlling the pressure in the process chambers PM1, PM2, is connected to the process chamber controller 239p through a serial line 40 for example. The process chamber controller 239p outputs control data (control command) for processing the product substrate and the dummy substrate, to the pressure controller 15, the valve for supplying/exhausting process gas, each kind of switch, a mass flow controller, and a temperature adjuster, etc., based on the process recipe prepared or edited by the operator through the operation controller 236 for example, and controls the substrate processing in the process chambers PM1, PM2.

Further, the storage part 16 storing barcodes 1, 2, 3 . . . indicating the carrier ID for identifying the carrier cassettes CA1 to CA3 placed on the load ports LP1 to LP3, is connected to the transfer controller 239t through the serial line 40 for example. The transfer controller 239t outputs the control data (control command) for transferring the product substrates and the dummy substrates to the vacuum robot VR, the atmosphere robot AR, each kind of valve, and switch, etc., based on the sequence recipe prepared or edited by the operator through the operation controller 236 for example.

### (4) Software Realized by the Controller

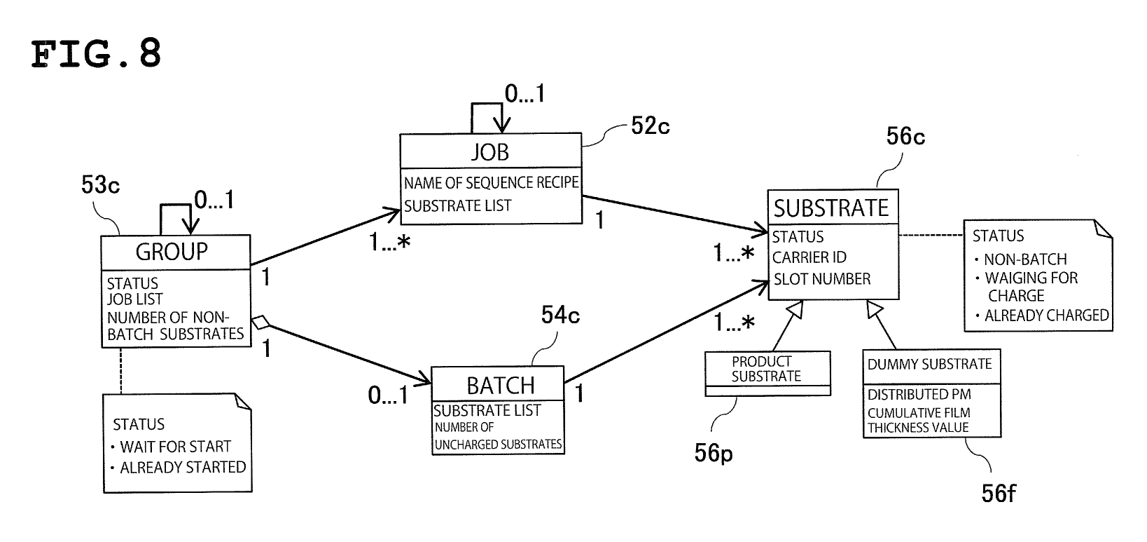

Prior to a functional description of the control part 239 being the controller, the relation of a main class and each class for managing a value and a state required for realizing such functions, will be described using FIG. 8. FIG. 8 is a class relation view of a relation of the main class of the software executed by the control part 239 of the substrate processing apparatus 10 according to this embodiment.

As shown in FIG. 8, the main class according to the control part 239 includes a substrate class 56c, a product substrate class 56p, a dummy substrate class 56f, a job class 52c, a batch class 54c, and a group class 53c. Each of these classes is instantized and can exist as objects on the software executed by the control part 239.

A substrate class 56c has a status as a member variable, and the “carrier ID” and the “slot number”. The status indicating the state of the substrate W includes “non-batch state”, “wait for charge” and “already charged”. The “non-batch state” indicates a state that the substrate W is not batch-assembled yet. The “wait for charge” indicates a state that the batch-assembled substrate W is set in a charge-waiting state into the load lock chambers LM1, LM2, and the “already charged” indicates a state that load into the load lock chambers LM1, LM2 is already requested. The “carrier ID” is an identification value capable of specifying the carrier cassettes CA1 to CA3 such as the aforementioned barcodes, etc. The “slot number” indicates slot positions of the carrier cassettes CA1 to CA3. Based on the “carrier ID” and the “slot number”, which slot position the substrate W belongs to in the carrier cassettes CA1 to CA3, can be specified.

The product substrate class 56p and the dummy substrate class 56f are inherited from the substrate class 56c. Further, the dummy substrate class 56f has the “distributed PM” and the “cumulative film thickness value” as member variables. The “distributed PM” is an identification value of the process chambers PM1, PM2 based on the distribution, when the dummy substrate used in each process chamber PM1, PM2 is distributed. The “cumulative film thickness value” indicates a value of a cumulative film thickness of a repeatedly used dummy substrate.

The job class 52c has a sequence recipe name and a substrate list as the member variables. Further, the job class 52c is set in a relation of 1 to 1 with respect to the substrate class 56c. The job object obtained by instantizing the job class 52c is configured so that a reference pointer of the substrate object is stored in the substrate list, to access the substrate object through the substrate list. Further, the job object is configured to indicate a generation order of the jobs by being associated with zero or more other job objects.

The batch class 54c has a role of managing the batch assembly of the substrates W, and has the substrate list and “the number of uncharged substrates” as member variables. Further, the batch class 54c has a relation of 1 to 1 with respect to the substrate class 56c. The “number of uncharged substrates” is the number of the substrates W whose status is in a state of the “wait for charge”. For example, in a case that the number of the substrates is five per 1 batch, an initial value of the “number of uncharged substrates” is five, and the number of uncharged substrates is subtracted by 1 every time the substrates W are charged. The batch object whose batch class 54c is instantized, is configured so that a reference pointer of the batch-assembled substrate object is stored in the substrate list, to access the substrate object through the substrate list.

The group class 53c has a role of managing the jobs having the same sequence recipes as a group, and has the status, the job list, and the “number of non-batch substrates” as member variables. Further, the group class 53c has a relation of 1 to 1 with respect to the job class 52c, and has zero or 1 batch object. The status showing a state of the job includes “wait for start” and “already started”. The “wait for start” indicates a state that the head of the job list is set in a waiting state for start, and the “already started” indicates a state that at least the job of the head of the job list is set in an already started state. The “number of non-batch substrates” is a total number of the substrates W whose status is set in the “non-batch” state, in the substrate objects associated with each related job. For example, when there is a group for managing two jobs, there are five substrates W whose status is “non-batch” in the substrates W associated with a first job, and when there are five substrates W whose status is “non-batch” in the substrates W associated with a second job, the “number of non-batch substrates” of this group is 30. The group object whose group class 53c is instantized, is configured so that the jobs having the same sequence recipes are stored in the job list according to an order of generating the jobs, to access the job object through the job list. Further, the group object is associated with zero or more other group objects, to thereby indicate an order of processing the group.

### (5) Functional Structure of the Controller

Subsequently, the functional structure of the control part 239 being the controller will be described using FIG. 9. FIG. 9 is a functional block diagram of the control part 239 of the substrate processing apparatus 10 according to this embodiment.

As shown in FIG. 9, the software realized by the control part 239 is mainly constituted of a message analyzer 51, a job controller 52, a group controller 53, a batch assembly unit 54, a PM management unit 55, and a material management unit 56.

The message analyzer 51 is configured to receive a message like a request and a notification, etc., from each controller such as the operation controller 236, or other unit provided in the control part 239, and distribute the message to other unit according to a content of the message.

The job controller 52 is configured to generate the job object, and is configured to deliver the generated job object to the group controller 53. Further, the job controller 52 is configured to associate the job objects with each other, and store the job objet in the job data 52d as the job list, and update the job list.

The group controller 53 is configured to generate the group object, and is configured to associate the group objects with each other and store the group object in the group data 53d as a group list, and update the group list, and further is configured to reference the job data 52d, and judge whether there is a job having the same sequence recipe as the sequence recipe of the job object delivered from the job controller 52. Further, the group controller 53 is configured to deliver the group object to the batch assembly unit 54, and give a request to load the substrate W which is batch-assembled by the batch assembly unit 54 into the load lock chambers LM1, LM2, and update the substrate data 56d, to thereby update the status of the substrate object. Moreover, the group controller 53 is configured to give a request to load the next substrate W into the load lock chambers LM1, LM2, if there is a batch being charged, on receiving a LM loading enabled notification (load lock chamber).

The batch assembly unit 54 is configured to generate the batch object and update the group data 53d so as to belong to the group object, and is configured to reference the job data 52d to acquire the job object, and reference the substrate data 56d based on the substrate list of the job object to acquire the substrate object. Further, the batch assembly unit 54 is configured to judge whether or not an adjustment of the number of substrates to be processed by the dummy substrate is necessary, and when it is so judged to be necessary, reference the substrate data 56d and decide the dummy substrate to be used.

The PM management unit 55 is configured to store in PM management data 55d a PM charging order showing an order of charge into the process chambers PM1, PM2, “PM cumulative film thickness values” being cumulative film thickness values of each process chamber PM1, PM2, and “frequency of processing of the PM substrate” being frequency of substrate processing in each process chamber PM1, PM2, or update the PM management data 55d.

The material management unit 56 is configured to judge the number of substrates to be processed in the charged carrier cassettes CA1 to CA3 when the carrier cassettes CA1 to CA3 are charged into the substrate processing apparatus 10, and generate the substrate object and store it in the substrate data 56d, and update the substrate data 56d, and is configured to set “distributed PM” when the substrates W are the dummy substrates, and update the “cumulative film thickness value”.

### (6) Operation of the Substrate Processing Apparatus

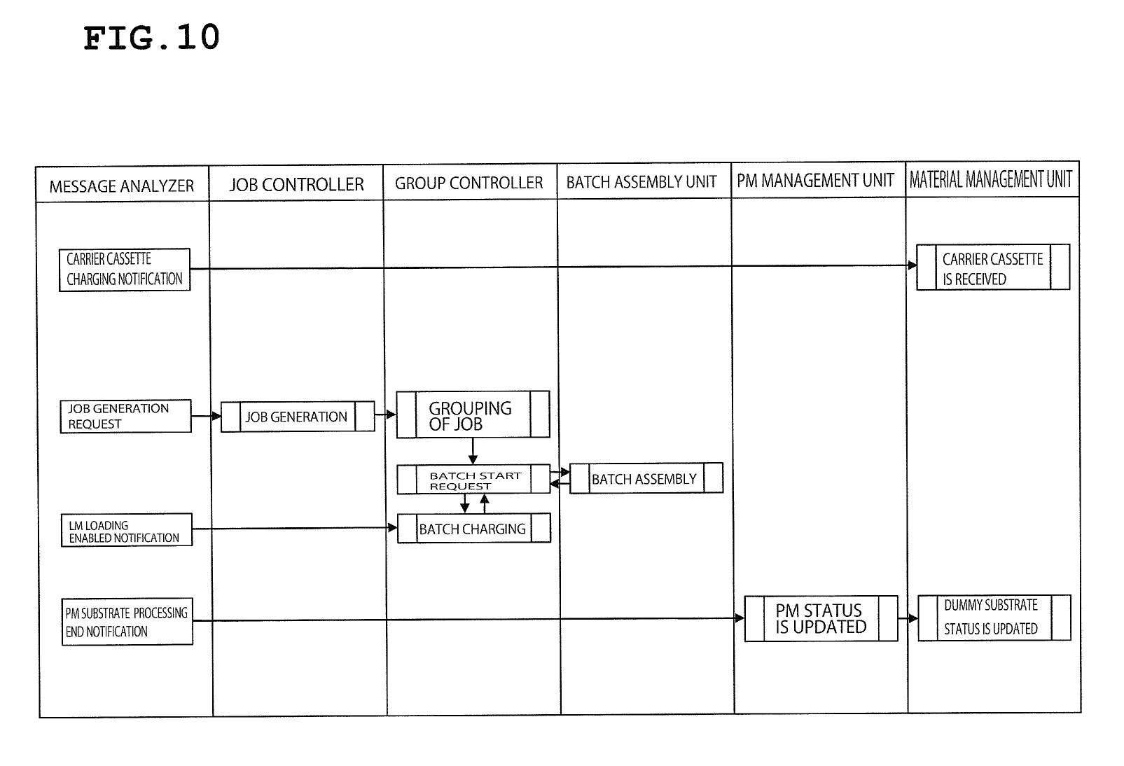

Next, the operation of the substrate processing apparatus 10 according to this embodiment will be described with reference to FIG. 1 and FIG. 10. FIG. 10 is a flowchart showing an outline of substrate processing steps in the substrate processing apparatus 10 according to this embodiment. In the description hereafter, the operation of each part of the substrate processing apparatus is controlled by the control part 239. Under such an operation and control, the substrate processing step is performed using an operating method of the dummy substrate or a sorting method of the substrate according to this embodiment, which is performed as a step of producing a semiconductor device.

(Transfer into the Atmosphere Transfer Chamber)

First, the gate valve at the vacuum transfer chamber TM side of the load lock chambers LM1, LM2 is closed, and the gate valve at the atmosphere transfer chamber EFEM side is opened, to vacuum-exhaust the inside of the vacuum transfer chamber TM and the inside of the process chambers PM1, PM2. Simultaneously, clean air is supplied into the atmosphere transfer chamber EFEM so that the inside of the atmosphere transfer chamber EFEM is set in approximately the atmospheric pressure.

When any one of the carrier cassettes CA1 to CA3 in which a plurality of substrates W are stored for example, is placed (charged) on any one of the load ports LP1 to LP3 after the aforementioned each part is prepared, the carrier ID for identifying the carrier cassette is read. Further, a carrier cassette charging notification is transmitted to the message analyzer 51.

As shown in FIG. 10, the message analyzer 51 that receives the carrier cassette charging notification, transmits this carrier cassette charging notification to the material management unit 56. When the carrier cassette charging notification is received, the material management unit 56 executes carrier cassette reception processing. Namely, the material management unit 56 judges whether the charged carrier cassette is the carrier cassette of the product substrates or the dummy substrates, and generate the substrate object according to each case, and distribute each dummy substrate to each process chamber PM1, PM2 in a case that the carrier cassette is the carrier cassette of the dummy substrates. Details of a flow of the “carrier cassette reception” processing will be described later.

Subsequently, when a job generation request is received, which is the request from the host computer 237u or by the operator through the operation controller 236, the message analyzer 51 transmits the job generation request to the job controller 52. When the job generation request is received, the job controller 52 executes job generation processing, and delivers the generated job object to the group controller 53. Details of the flow of the “job generation” will be described later.

By receiving the above processing, the group controller 53 generates the group object and performs a grouping processing, and further executes a batch start request processing. In the batch start request processing, the group object is delivered to the batch assembly unit 54 from the group controller 53, and the batch assembly unit 54 executes a batch assembly processing based on the information regarding the delivered group object, to thereby generate the batch object. The group controller 53 receives the batch object from the batch controller 54, and continues the batch start request processing based on the information, and gives a request of loading the substrate W of the head of the batch into either the load lock chamber LM1 or LM2. Details of each flow of the “job grouping” process, the “batch start request” processing, and the “batch assembly” processing will be described later.

When the loading request is given by the group controller 53, the atmosphere robot AR transfers the substrate W of the head of the batch whose loading request is given from the group controller 53, into the atmosphere transfer chamber EFEM from a prescribed slot in the carrier cassette as shown in FIG. 1, which is then set on an orientation flat aligner not shown, to thereby execute aligning, etc., of a crystal orientation.

(Transfer into the Vacuum Transfer Chamber)

Subsequently, the atmosphere robot AR pick-ups the substrate W on the orientation flat aligner, and transfers it into the load lock chamber LM1 in a state that the gate valve is opened, which is the gate valve at the atmosphere transfer chamber EFEM side of at least one of the load lock chambers, for example, the load lock chamber LM1. Then, the gate valve at the atmosphere transfer chamber EFEM side is closed, to vacuum-exhaust the inside of the load lock chamber LM1. When the pressure of the inside of the load lock chamber LM1 is reduced to a prescribed pressure, the gate valve at the vacuum transfer chamber TM side is opened while closing the gate valve at the atmosphere transfer chamber EFEM side. Then, the substrate W set in the load lock chamber LM1 is picked-up by the vacuum robot VR, and is transferred into the vacuum transfer chamber TM.

During this period, transfer of the substrate W into the vacuum transfer chamber TM using the load lock chamber LM2 is simultaneously progressed. Namely, while reducing the pressure of the load lock chamber LM1 into which the substrate W is transferred, the loading request is also given regarding the second substrate W of the batch, and the second substrate W is transferred into the load lock chamber LM2, and into the vacuum transfer chamber TM based on the same procedure as the aforementioned procedure.

Thus, the transfer of the substrate W into the load lock chambers LM1, LM2, and the transfer of the substrate W into the vacuum transfer chamber TM from the load lock chambers LM1, LM2 are completed, and when the transfer of the substrate W into the load lock chambers LM1, LM2 are enabled again, the message analyzer 51 receives the LM loading enabled notification and transmits it to the group controller 53. The group controller 53 which receives the LM loading enabled notification, executes a batch charge processing. In the batch charge processing, if there is a batch being charged, the LM (load lock chamber) loading request is given regarding the next substrate W, and the transfer of the substrate W into the load lock chambers LM1, LM2 is continued. Details of the flow of the “batch charge” processing will be described later.

(Transfer into the Process Chamber)

When the substrate W is transferred into the vacuum transfer chamber TM, the gate valve at the process chamber PM1 side is opened for example, to transfer the substrate W into the process chamber PM1, and set it on a substrate placement table ST11. The transfer of the substrate W into the process chamber PM1 based on the aforementioned batch charge processing is performed in such a manner that the numbers of substrates W that can be processed in the process chamber PM1 are transferred, and the transfer is repeated until all substrate placement tables ST11 to ST15 in the process chamber PM1 are filled with the substrates W.

Namely, the group controller 53 continues the batch charge processing until the charge of all substrates W in the batch is completed. Further, after completion of the batch charge processing, the group controller 53 executes the batch start request processing again, and performs the charge processing of the next batch into the process chamber PM2.

### (Processing in the Process Chamber)

After the prescribed numbers of substrates W are transferred into the process chamber PM1, the process gas is supplied into the process chamber PM1 and the substrates W are heated, to thereby execute prescribed processing such as film formation processing using plasma, etc., to the substrates W. At this time, the same or different substrate processing is simultaneously progressed in some cases in the process chamber PM2 as well.

Here, if the substrate processing is performed in a state that all substrate placement tables are not filled, and in a state that the number of substrates does not reach the number of substrates of 1 batch, unnecessary film formation or etching, etc., is applied to the substrate placement table on which the substrate is not loaded, according to the content of the substrate processing. Particularly, in the substrate processing using plasma, a variation of electric characteristics and a variation of a substrate processing performance are generated on the substrate placement table which is also a plasma electrode, thus deteriorating the film formation characteristic and etching characteristic in some cases.

According to this embodiment, prescribed numbers of the product substrates and the dummy substrates are combined to form 1 batch, so as to fill all substrate placement tables ST11 to ST15. Therefore, the substrates W are placed on all substrate placement tables ST1 to ST15, and unnecessary substrate processing is prevented from being applied to the substrate placement tables ST11 to ST15. Therefore, substrate processing characteristics such as film formation characteristic and etching characteristic can be stable.

When the processing of the substrates W in the process chamber PM1 is completed, the message analyzer receives the PM (process chamber) substrate processing end notification as shown in FIG. 10. The message analyzer 51 transmits the PM substrate processing end notification to the PM management unit 55. When the PM substrate processing end notification is received, the PM management unit 55 performs PM status update processing, to thereby update the status of the process chamber PM1 such as the “PM cumulative film thickness value”, etc., being the cumulative film thickness value of a deposited film formed in the process chamber PM1. Further, data of this film thickness value is delivered to the material management unit 56. The material management unit 56 performs dummy substrate status update processing, so that update of adding the film thickness value to the cumulative film thickness value of the currently used dummy substrate, is added to the dummy substrate object. Details of each flow of the “PM status update” processing and the “dummy substrate status update” processing will be described later.

(Transfer into the Load Lock Chamber)

When all required processing is completed, the processed substrate W set on the substrate placement tables ST11 to ST15 in the process chamber PM1 for example, is picked-up by the vacuum robot VR, which is then transferred into the load lock chamber LM1 by opening the gate valve at the vacuum transfer chamber TM side of the load lock chamber LM1, and is disposed on a buffer stage. Thereafter, the gate valve at the vacuum transfer chamber TM side is closed, and the clean gas is supplied into the load lock chamber LM1 to return the inside of the load lock chamber LM1 to approximately the atmospheric pressure, and the gate valve at the atmosphere transfer chamber EFEM side is opened.

### (Storage in the Carrier Cassette Placed on the Load Port)

Subsequently, the processed product substrate set in the load lock chamber LM1 is picked-up by the atmosphere robot, and is transferred to the carrier cassette CA1 placed on the load port LP1 for example, and is stored in a vacant slot. Further, if there is the dummy substrate set in the load lock chamber LM1, the dummy substrate is picked-up and is transferred to the carrier cassette C3 placed on the load port LP3 for example, and is stored in the vacant slot. When all the processed substrates W are stored in the prescribed carrier cassettes CA1, C3, etc., the carrier cassette C3 in which the dummy substrate is stored, is remained to be resident in the load port LP3, and in this state, the carrier cassette CA1 in which the processed product substrate is stored, is unloaded from the load port LP1, to complete automatic transfer processing.

### (7) Reception Processing of the Carrier Cassette

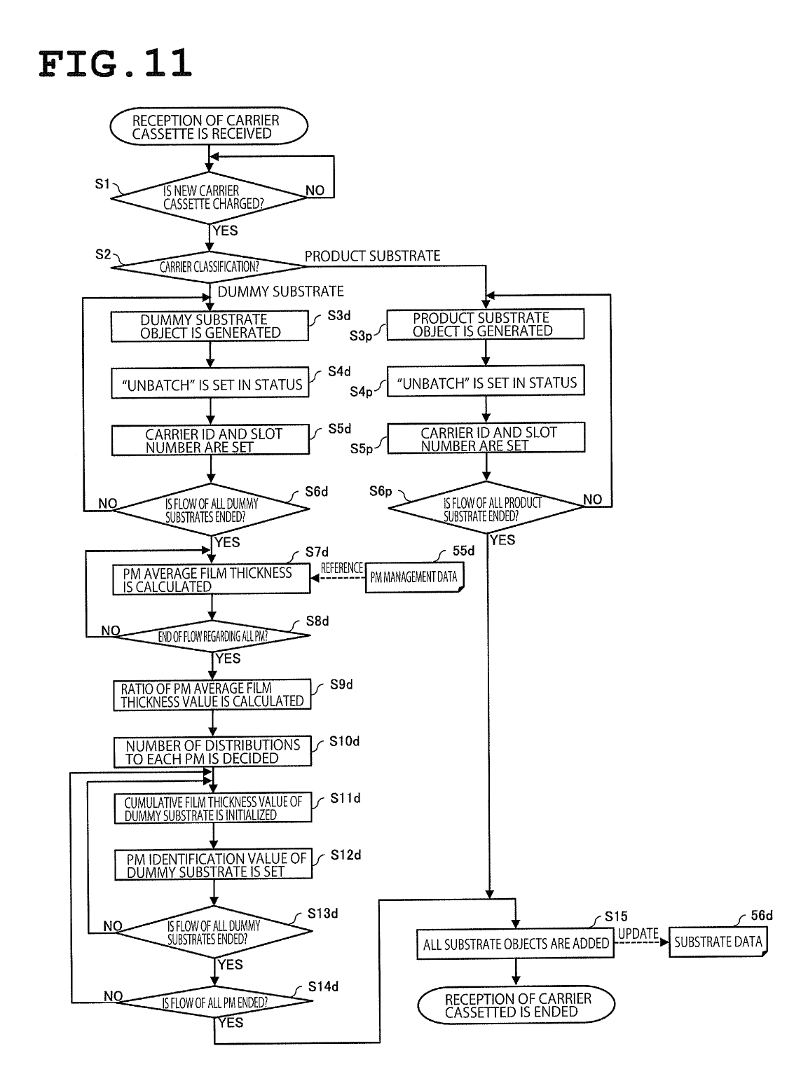

Subsequently, the aforementioned each flow will be described further in detail. First, the flow of carrier cassette reception processing will be described using FIG. 11. FIG. 11 is a flowchart of the carrier cassette reception processing by the material management unit 56 executed by the controller 239 according to this embodiment.

A technique of distributing each kind of substrate will be described based on the flowchart of FIG. 11, which is executed when the carrier cassette is placed on the load port.

First, the substrate object is generated and the member variables are set.

Namely, as shown in FIG. 11, when the carrier cassette in which a plurality of substrates W are stored, is placed on any one of the load ports LP1 to LP3 (S1), the material management unit 56 judges a type of the placed carrier cassette (S2). In a case of the carrier cassette exclusive for the product substrates, the number of substrates in the carrier cassette is judged, and the product substrate object is generated (S3p). In a case of the carrier cassette exclusive for the dummy substrates, the number of substrates in the carrier cassette is judged, and the dummy substrate object is generated (S3d). Next, the “non-batch” is set in the status of each substrate object (S4p, S4d), and the carrier ID of the carrier cassette in which the substrate W is stored, is set as the “carrier ID” of the substrate object, and the number of slot on which the substrates W are stacked is set as “slot numbers” (S5p, S5d). As described above, all of the S3p to S5p and S3d to S5d are performed for all substrates W (S6p, S6d).

Subsequently, the number of dummy substrates used in each process chamber is distributed.

Namely, when the charged carrier cassette is the carrier cassette exclusive for the dummy substrates, the PM average film thickness value is calculated by dividing the cumulative film thickness value (PM cumulative film thickness value) of a prescribed process chamber by the frequency of substrate processing (frequency of PM substrate processing), with reference to the PM management data 55d. After the PM average film thickness value for all process chambers PM1, PM2 is obtained (S8d), the ratio of each PM average film thickness value is calculated (S9d), and the number of the dummy substrates distributed to each process chamber PM1, PM2 is decided based on the obtained ratio (S10d). Namely, the number of dummy substrates is distributed, so that a value obtained by dividing the average film thickness value of the deposited film formed per one processing in a prescribed process chamber, by the number of the dummy substrates distributed to this process chamber, is approximately the same value between the process chambers PM1 and PM2.

Next, the member variables of the dummy substrate are set.

Namely, the “cumulative film thickness value” of all dummy substrate objects is initialized (Slid), and a PM identification value of each process chamber PM1, PM2 is set as “distributed PM” (S12d). This operation is performed for all dummy substrates (S13d), and further performs for all process chambers PM1, PM2 (S14d). At this time, the dummy substrate distributed to the same process chamber is made to be a continuous slot, and order of smaller or larger PM identification values is arranged in an order from a smaller slot number.

Finally, all substrate objects of the product substrates and the dummy substrates are added to the substrate data 56d (S15). As described above, the carrier cassette reception processing is ended.

According to this embodiment, the dummy substrate is distributed to the process chamber in which the average film thickness value of the deposited film formed in each process chamber PM1, PM2 per one processing is large, so that the number of distributed substrates becomes large. Thus, the following conventional problem is prevented. Namely, in an operation of managing the dummy substrate by the lot for each carrier cassette, anyone of the dummy substrates in the lot has a thickness exceeding a prescribed cumulative film thickness value, and therefore when the dummy substrate is exchanged for each lot, the dummy substrate with a small cumulative film thickness value is also exchanged and disposed, thus reducing a use efficiency.

For example, when the substrate processing is performed using the sequence recipe of parallel processing for specifying each process chamber in the substrate processing apparatus including two process chambers, it is assumed that the film thickness value per one processing in each process chamber is 200 Å and 100 Å respectively. Further, twenty-four dummy substrates are resident in the substrate processing apparatus, and twelve substrates each are equally distributed to each process chamber, and when any one of the cumulative film thickness values reaches 10000 Å, the dummy substrate is exchanged together with the lot.

Under the aforementioned condition, when the dummy substrate to be used is equally distributed to each process chamber to suppress a cross contamination across process chambers, and when it is assumed that the dummy substrate distributed to each process chamber is used for the same number of times, the cumulative film thickness value of one of the distributed dummy substrates simply reaches 5000 Å at a time when it should be exchanged, when the cumulative film thickness value of the other distributed dummy substrate reaches 10000 Å. This means that the other dummy substrate is exchanged in a state that the cumulative film thickness value is half of a defined value, resulting in a reduction of the use efficiency and increase of the cost. However, according to this embodiment, a use state of each dummy substrate can be approximately equally arranged even in a case that the content of the substrate processing is different in each process chamber PM1, PM2, and the use efficiency of the dummy substrate as a whole can be improved. Therefore, consumption of the dummy substrates can be suppressed, and the frequency of exchange is reduced, thus making it possible to reduce the cost. Further, frequency of stagnation of the substrate processing due to exchange of the dummy substrate is reduced, and the production efficiency of the substrate processing apparatus 10 is improved.

Further, in a case of different contents of the substrate processing in each process chamber, there is a risk of affecting the characteristic of the substrate processing when the dummy substrate processed in a prescribed process chamber is loaded into other process chamber. Moreover, even in a case of the process chambers for applying the same substrate processing, a plurality of particles are generated in some cases due to some factors compared with other process chamber, and when the dummy substrate processed in the process chamber in which there are a plurality of particles, is loaded into other process chamber, there is a risk of causing a diffusion of the particles. However, in this embodiment, for example the dummy substrate in the carrier cassette C3 is distributed to each process chamber PM1, PM2, and the dummy substrate is loaded into the distributed process chamber only, and therefore the diffusion of the particles (cross contamination) by the dummy substrate as described above, can be suppressed.

### (8) Job Generation Processing and Grouping Processing

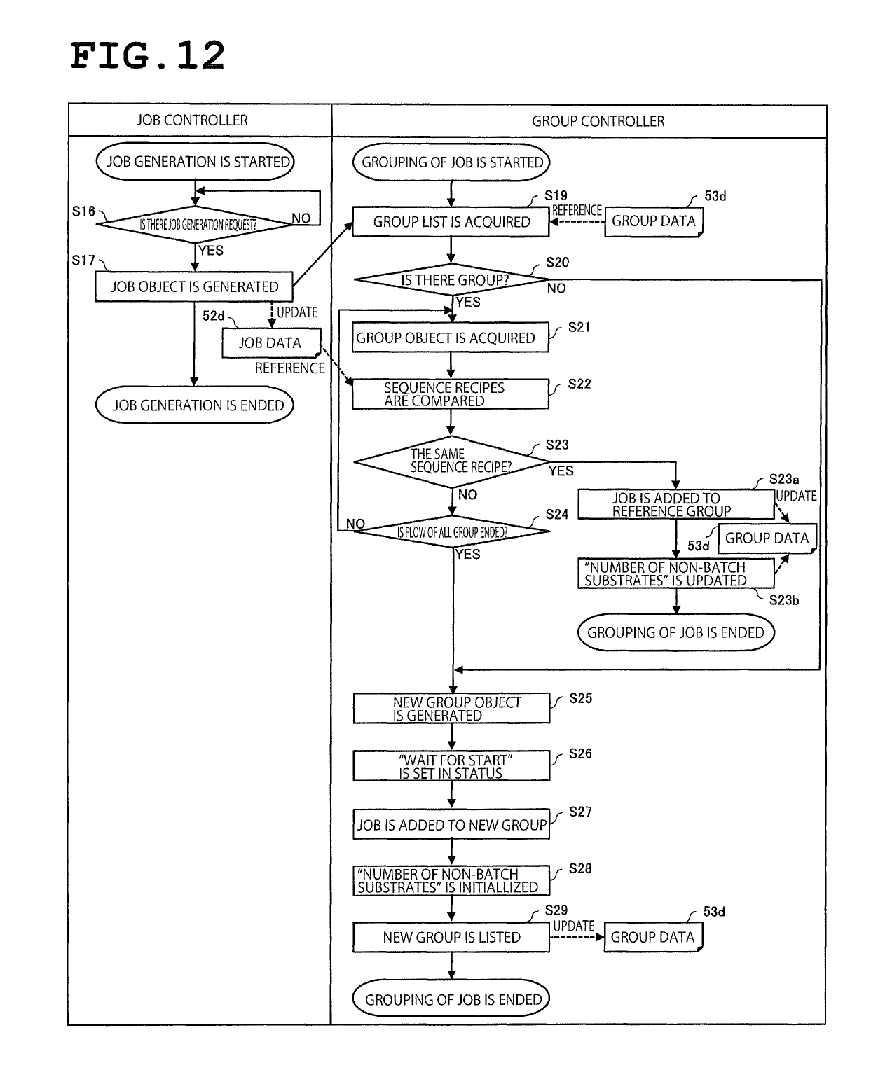

Next, each flow of the job generation processing and the grouping processing of jobs will be described using FIG. 12. FIG. 12 is a flowchart of the job generation processing by the job controller 52 and the grouping processing of jobs by the group controller 53 possessed by the control part 239 according to this embodiment.

In this embodiment, the grouping processing is performed for collecting different jobs having the same sequence recipes into the same group, and the substrate processing is executed by performing batch assembly for each group unit as described below. Thus, for example when multiple lots are processed based on the same sequence, the product substrates of different lots are batch-assembled, and can be processed collectively. Therefore, the frequency of adjusting the number of the dummy substrates in each lot can be reduced, and the frequency of use of the dummy substrates can be reduced.

A specific job grouping technique will be described hereafter, based on the flowchart of FIG. 12.

First, the job is generated by the job controller 52.

Namely, as shown in FIG. 12, when the job generation request is received through the message controller 51 (S16), the job object is newly generated (S17), and further the job data 52d is updated, and the generated job object is delivered to the group controller 53. As described above, the job generation processing is ended.

Subsequently, right or wrong of adding the job object to the existent group is judged, and addition to the existent group or generation of the new group object are performed.

Namely, the group controller 53 acquires the group list showing a relation between the group objects, with reference to the group data 53d (S19), and judges presence/absence of the group object (S20). Namely, when the carrier cassette of the product substrate is newly charged and the job generation request is transmitted in a state that the carrier cassette of the product substrate is not charged into the substrate processing apparatus 10 for example, there is no presence of the group object. In this case, the group controller 53 newly generates the group object (S25), and sets “wait for start” in the status (S26), and adds a pointer of the delivered job object to the job list, to thereby add the job to a new group (S27), and initializes the “number of non-batch substrates” to zero (S28). Further, the generated group object is listed, and the group data 53d is updated (S29).

Meanwhile, when the carrier cassette of the product substrate is newly charged and the job generation request is transmitted when the carrier cassette of the product substrate is already charged into the substrate processing apparatus and the job is being executed, there is already a presence of the group object. Further, when there are a plurality of jobs having different sequence recipes, there are a plurality of group objects. In this case, the group controller 53 takes out the group object from the head of the group list (S21), and compares the sequence recipe name of the taken-out group object and the sequence recipe name of the job object delivered from the job controller 52 (S22), and judges whether or not these sequence recipe names are matched with each other (S23).

When the sequence recipe names are mismatched, the group controller 53 takes-out the next group object from the group list and compares the sequence recipe names similarly. Thus, the group controller 53 compares the sequence recipe names of all group objects (S24), and in a case of a mismatch of the sequence recipe names, the processing after S25 is performed. In a case that the sequence recipe names are matched with each other, the pointer of the delivered job object is added to the end of the job list of this group object (S23a), and the number of substrates associated with the job is added to the “number of non-batch substrates”, to thereby update the group data 53d (s23b).

As described above, the grouping processing of jobs is ended.

Thus, in this embodiment, the product substrate can be collectively processed in one process chamber, even if the lot of the product substrate is different. Therefore, the frequency of adjusting the number of substrates to be processed for each job and each lot using the dummy substrates, is reduced, thus making it possible to reduce the frequency of use of the dummy substrates. Accordingly, the consumption of the dummy substrates can be suppressed, and the frequency of exchange is reduced, thus making it possible to reduce the cost. Further, the number of substrates to be processed is reduced in the whole body of the substrate processing apparatus 10, and the frequency of stagnation of the substrate processing due to the exchange of the dummy substrates is reduced, and the production efficiency is improved.

### (9) Batch Start Request Processing

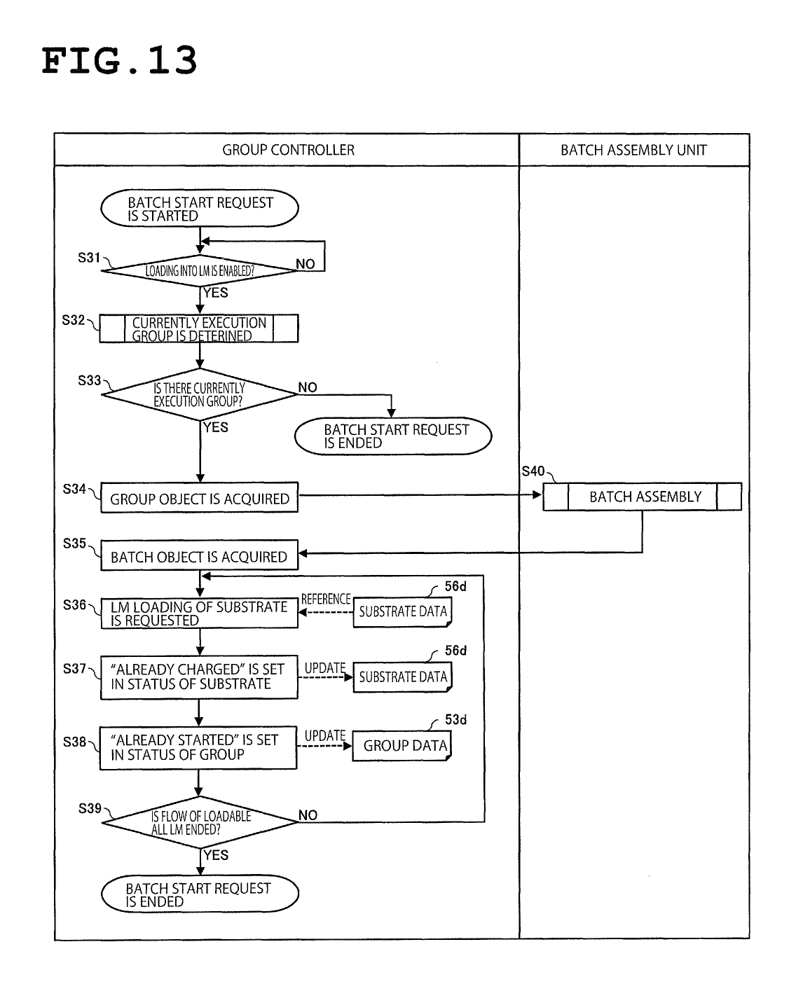

Next, the flow of the batch start request processing will be described using FIG. 13. Further, “currently execution group decision” processing executed in the batch start request processing will also be described together. FIG. 13 is a flowchart of the batch start request processing by the group controller 53 possessed by the control part 239 according to this embodiment.

In the batch start request processing that comes after the grouping processing of jobs, a request for loading into the load lock chambers LM1, LM2 is given, to start the charge of the substrate W of the head of the batch, into the load lock chambers LM1, LM2.

Namely, as shown in FIG. 13, the group controller that ends the grouping processing of jobs, judges whether or not loading of the substrates W into either the load lock chamber LM1 or LM2 is allowed (S31). When the substrates W can be loaded, currently execution group decision processing as will be described later is executed (S32).

When there is a group that can be executed (S33), the group controller 53 acquires the group object (S34), and delivers it to the batch assembly unit 54. The batch assembly unit 54 to which the group object is delivered, performs batch assembly processing as will be described later to generate a batch object (S40), and delivers it to the group controller 53 (S35).

The group controller 53 references the substrate data 56d of the batch object acquired from the batch assembly unit 54, and gives a loading request to either the load lock chamber LM1 or LM2 regarding the substrate W corresponding to the substrate object of the head of the substrate list (S36). Next, “already charged” is set in the status of the substrate object, and the substrate data 56d is updated (S37), and “already started” is set in the status of the group object corresponding thereto, so that the group data 53d is updated (S38). Further, if there is a load lock chamber into which the substrate can be loaded, the aforementioned processing of S36 to S38 are repeated for all load lock chambers LM1, LM2 into which the substrate can be loaded (S39).

As described above, the batch start request processing is ended.

### (Currently Execution Group Decision Processing)

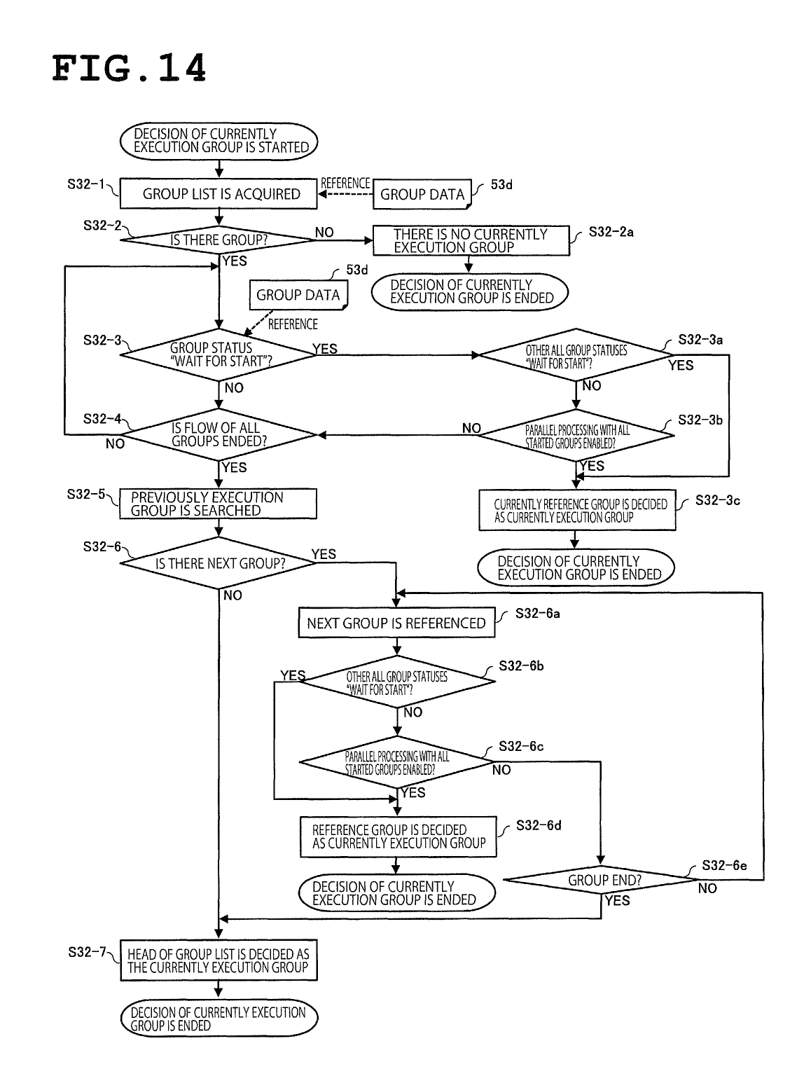

Subsequently, the currently execution group decision processing executed in the batch start request processing will be described using FIG. 14. FIG. 14 is a flowchart of the currently execution group decision processing by the group controller 53 possessed by the controller 239 according to this embodiment.

In the currently execution group decision processing, a currently execution group is decided according to presence/absence of other group in which the substrate processing is already started, and according to right or wrong of the parallel processing with the already started group.

Namely, as shown in FIG. 14, the group controller 53 acquires the group list from the group data 53d (S32-1), and judges the presence/absence of the group object (S32-2). When there is no group object, it is assumed that there is no currently execution group, and the processing is ended (S32-2A).

When there is the group object, the group data 53d is referenced, and whether or not the status is set in the “wait for start” is judged regarding the group object of the head of the group list (S32-3). When the status is set in a state excluding the “wait for start”, the next group object of the group list is referenced, and judgment is repeated until the reference of all group objects is ended (S32-4).

When the status of the referenced group object is set in the “wait for start”, whether the status of all other group objects is set in the “wait for start” is judged (S32-3a), and when the status is set in the “wait for start”, the currently referenced group object is decided as a currently execution group (S32-3c). Meanwhile, when there is a group object of the “already started”, whether or not the parallel processing of all group object already started and group object currently referenced is allowed (S32-3b), is judged. When the parallel processing is allowed, the currently referenced group object is decided as the currently execution group (S32-3c). When the parallel processing is not allowed, the next group object of the group list is referenced, and the judgment is repeated until the reference of all group objects is ended (S32-4).

When the currently execution group is not decided in the processing heretofore, a previously execution group is searched (S32-5), and presence/absence of the group object next to the previously execution group is judged (S32-6). When there is no next group object, the group object of the head of the group list is decided as the currently execution group (S32-7).

When there is the next group object, this group object is decided as a reference group object (S32-6a), and whether the status of all other group objects is set in the “wait for start” is judged (S32-6b), and when other all group objects are set in the “wait for start”, the reference group object is decided as the currently execution group (S32-6d). Meanwhile, when there is the group object set in the “already started”, whether or not the parallel processing of all already started group object and the reference object is allowed, is judged (S32-6c). When the parallel processing is allowed, the reference group object is decided as the currently execution group (S32-6d). When the parallel processing is not allowed, the next group object in the group list is referenced, and the judgment is repeated until the reference of the group object of the end is completed (S32-6e). When group object of the end is referenced, and the currently execution group is not decided, the group object of the head of the group list is decided as the currently execution group (S32-7).

As described above, the currently execution group decision processing is ended. The batch assembly is performed as described above, to the currently execution group thus decided, and the charge of the batch is started when the batch start request processing is received. After starting the charge of the batch, transfer of the substrate W in the second round or thereafter is executed into each load lock chamber LM1, LM2 by batch charge processing as will be described later, and thereafter transfer of all batches is executed by repeating the batch start request processing and the batch charge processing.

### (10) Batch Assembly Processing

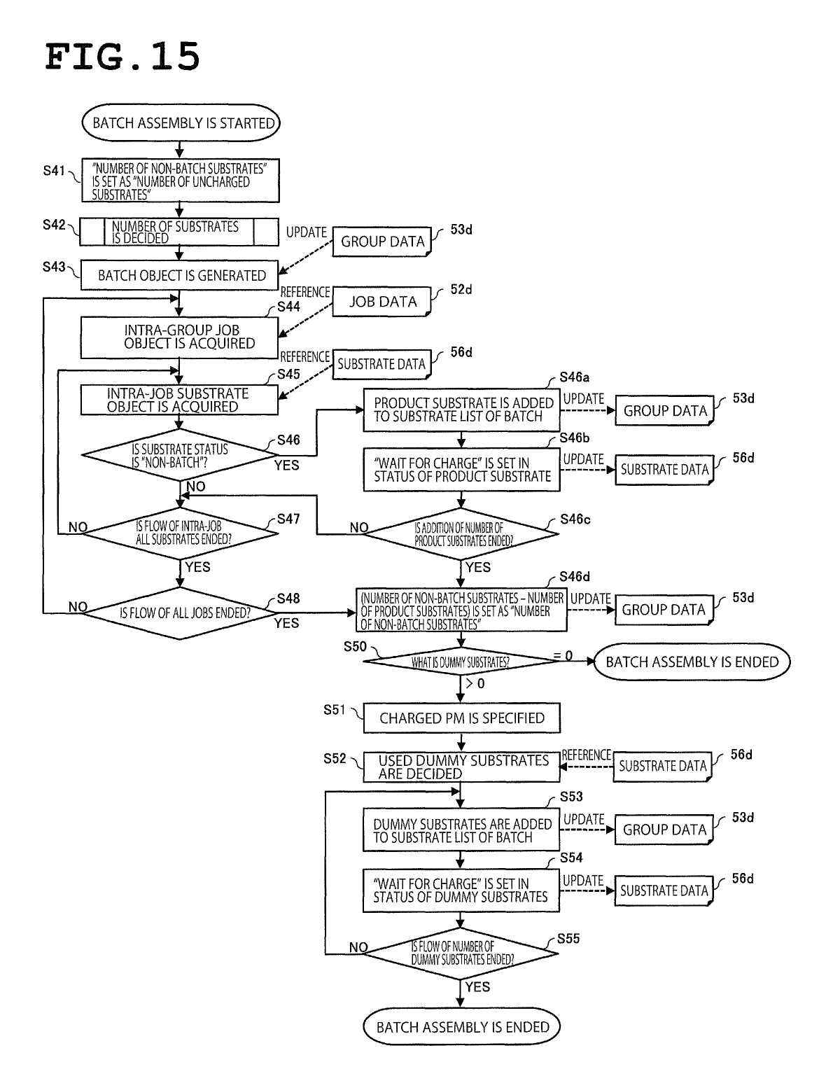

Next, the flow of the batch assembly processing will be described. Further, “substrate number decision” processing executed in the batch assembly processing, and “dummy preferentially use PM order decision processing” executed in the substrate number decision processing will also be described together. FIG. 15 is a flowchart of the batch assembly processing by the batch assembly unit 54 possessed by the control part 239 according to this embodiment.

The batch assembly processing performed by indicating the product substrates and the dummy substrates by prescribed numbers each, will be described based on the flowchart of FIG. 15.

As shown in FIG. 15, the batch assembly unit 54 references the group object delivered from the group controller 53, and sets the “number of non-batch substrates” in the group object as the “number of non-charged substrates” (S41), and executes the substrate number decision processing of deciding the numbers of the product substrate and the dummy substrate to be batch-assembled (S42). Details of the flow of the “substrate number decision” processing will be described later.

Next, the product substrate is designated and added to the batch.

Namely, the batch assembly unit 54 newly generates the batch object, which is then associated with the group object, so that the group data 53d is updated (S43). Next, the flow regarding the product substrates is performed as described below. Namely, the job data 52d of the group object is referenced, and the job object of the head of the job list is acquired (S44). Subsequently, the substrate data 56d of the obtained job object is referenced and the substrate object of the head of the substrate list is acquired (S45), and whether the status of this substrate object is set as the “non-batch” is judged (S46).

When the status of the substrate object is set as the “non-batch”, the pointer of the substrate object is added to the substrate list of the batch object so that a prescribed product substrate is added to the batch, and the group data 53d is updated (S46a). Next, “wait for charge” is set in the status of the substrate object, and the substrate data 56d is updated (S46b). After repeating the aforementioned S45 to S46 until addition of the number of product substrates is ended (S46c), a value obtained by subtracting the number of product substrates from the number of non-batch substrates is set as the “number of non-batch substrates”, and the group data 54d is updated (s46D).

When the status of the substrate object is not the “non-batch”, similar processing is performed to the next substrate object in the substrate list, and the processing is repeated until the number of the product substrates reaches a prescribed number or reaches the end of the substrate list (S47). When the added product substrates do not satisfy a prescribed number, the next job object in the job list is acquired, and similar processing is repeated until the number of the product substrate reaches a prescribed number or all jobs in the group is ended (S48).

Next, the dummy substrate is designated as needed and added to the batch.

Namely, the batch assembly unit 54 judges whether or not the addition of the dummy substrates is necessary (S50), and when there is no necessity for adding the dummy substrates (the number of the dummy substrates=0), the batch assembly processing is ended. When there is a necessity for adding the dummy substrates (the number of the dummy substrates>0), the process chamber into which the batch is charged, is specified (S51). Then, the substrate data 56d is referenced and all dummy substrate objects distributed to this process chamber are extracted, and the dummy substrate with a minimum cumulative film thickness value is decided as a substrate to be used (S52). When the substrate to be used is decided, the pointer of the substrate object of the dummy substrate to be used, is added to the substrate list of the batch object, and the group data 53d is updated (S53). Further, the “wait for charge” is set in the status of this substrate object, so that the substrate data 56d is updated (S54). The aforementioned processing is repeated until the number of the dummy substrates reaches a prescribed number (S55).

As described above, the batch assembly processing is ended.

As described above, in the batch assembly processing in this embodiment, prescribed product substrates and the dummy substrates are designated by prescribed numbers each, to thereby perform the batch assembly. At this time, the dummy substrate is designated in an order of a smaller cumulative film thickness value, so that the dummy substrates used in the process chamber are equally used as much as possible. Thus, a deviation in a use state of the dummy substrates in each process chamber PM1, PM2 is reduced, and the use efficiency of the dummy substrates can be improved.

Conventionally, when a plurality of processing is applied to the product substrates included in 1 lot in a plurality of process chambers, the batch assembly using the dummy substrates is fixed to a last batch or a first batch per one processing. Therefore, when the processing is applied to a plurality of batches sequentially in a plurality of process chambers, the deviation is generated in the frequency of use and the sheet number of the dummy substrates, in the process chamber that hits the batch including the dummy substrates, and the other process chamber. Further, the batch assembly using the dummy substrates is fixed to the head or the end of the lot, and similarly as described above, the deviation is generated in a plurality of process chambers. Since the batch assembly is usually performed for each lot, the same thing can be said for a case that the same processing is applied to multiple lots. Further, with a tendency of various types of products in small lots, number adjustment by the dummy substrates in the aforementioned structure needs to be performed frequently, thus increasing the frequency of use of the dummy substrates. According to this embodiment, the deviation in the frequency of use and sheet number of the dummy substrates can be suppressed.

### (Substrate Number Decision Processing)

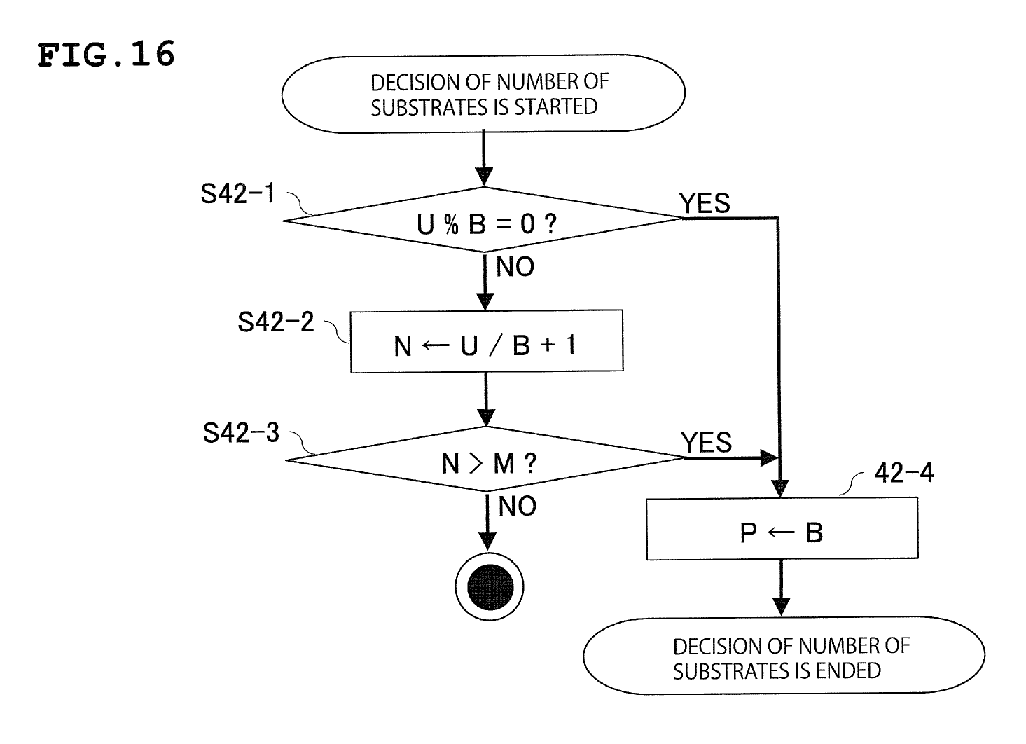

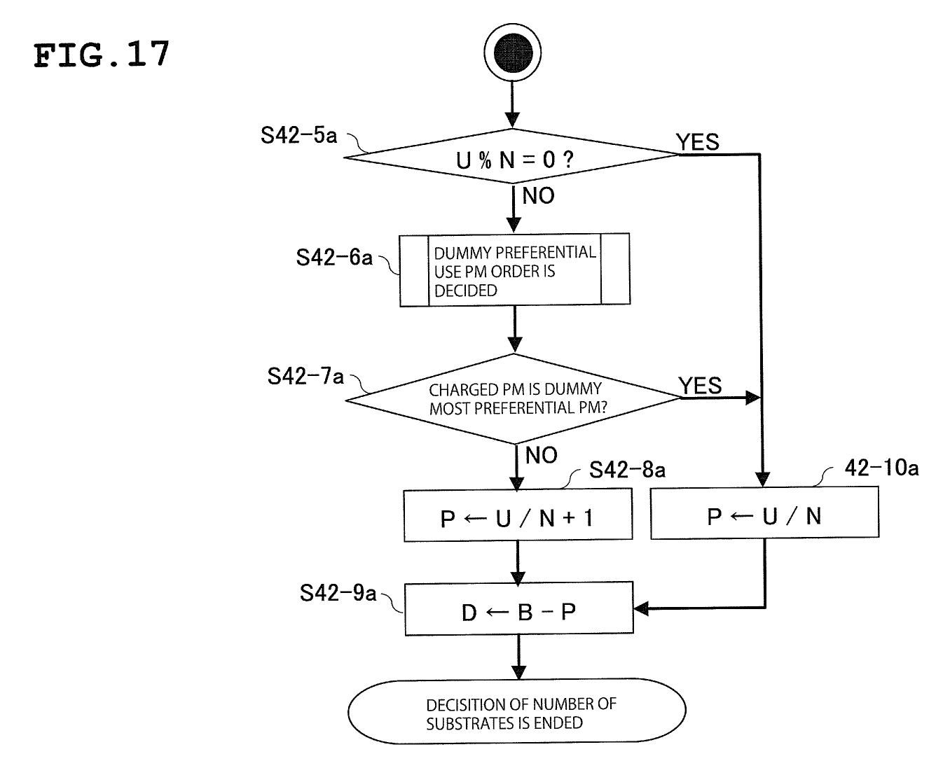

Subsequently, the substrate number decision processing executed in the batch assembly processing will be described using FIG. 16 to FIG. 19. FIG. 16 is a flowchart showing a former half of the substrate number decision processing by the batch assembly unit 54 possessed by the control part 239 according to this embodiment. FIG. 17 to FIG. 19 are views of a latter half of the substrate number decision processing by the batch assembly unit 54 possessed by the control part 239 according to this embodiment, and are flowcharts in a case of using algorithms A1, A2, A3 respectively.

In the substrate number decision processing, the numbers of product substrates and the dummy substrates in the batch are decided based on a prescribed algorithm. The substrate number decision processing based on several algorithms is shown as an example hereafter. In FIG. 16 to FIG. 19, and in the description hereafter, “U” indicates the number of unprocessed product substrates, “B” indicates the number of batch substrates, “N” indicates the number of batches, “M” indicates the number of process chambers, “P” indicates the number of product substrates in the batch, and “D” indicates the number of dummy substrates. For example, in the aforementioned substrate processing apparatus 10, the number of batch substrates “B” is “5”, and the number of process chambers “M” is “2”.

First, processing at the time of eliminating the dummy substrates will be described.

Namely, as shown in FIG. 16, the number of unprocessed product substrates U is divided by the number of batch substrates B, to thereby calculate a remainder (S42-1), and when the remainder is zero, the number of batch substrates B is set as the number of product substrates P in the batch (S42-4).

When the remainder is zero, a value obtained by adding 1 to the value obtained by dividing the number of unprocessed product substrates U by the number of batch substrates B, is set as the number of batches N (S42-2). The number of batches N and the number of process chambers M are compared (S42-3), and when the number of batches N is larger than the number of process chambers M, the number of batch substrates B is set as the number of product substrates Pin the batch (S42-4).

Next, processing for requiring the dummy substrate will be described.

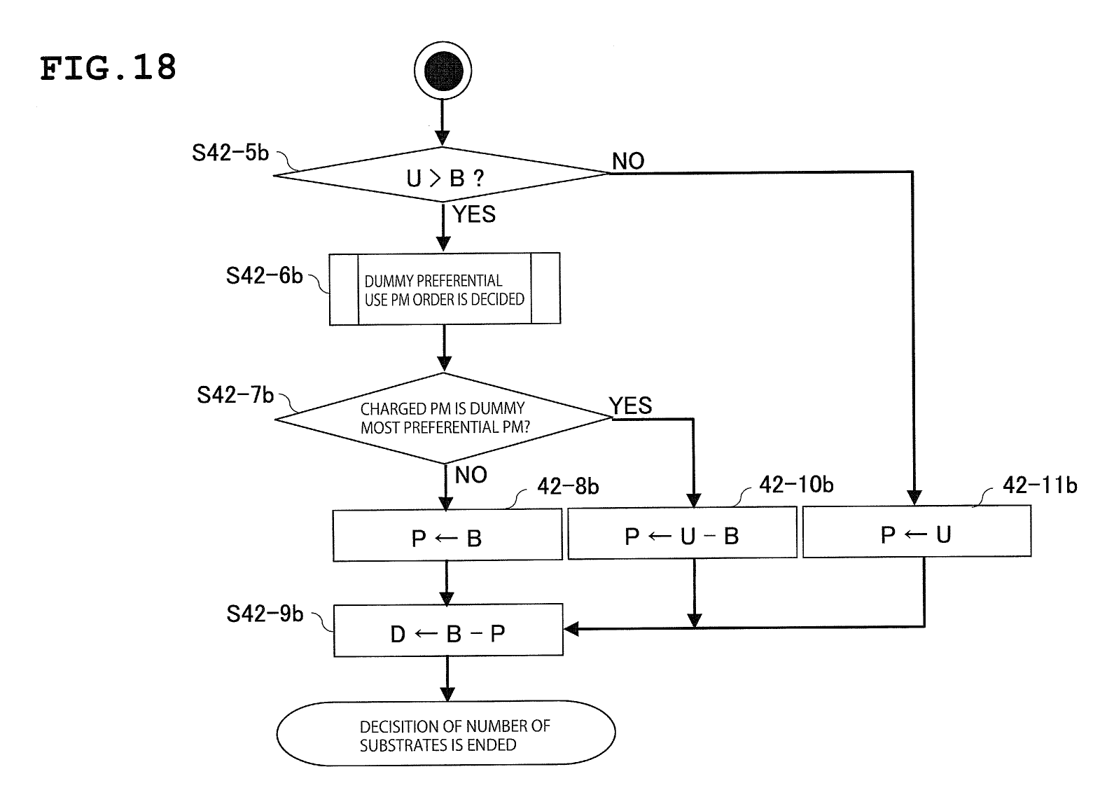

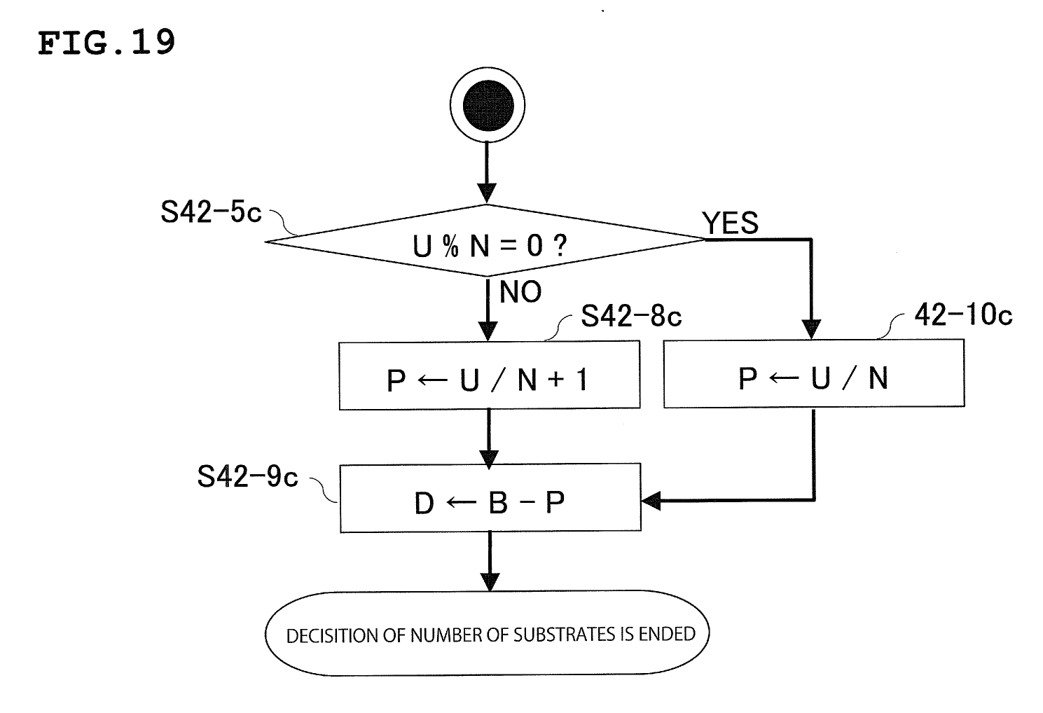

Namely, the dummy substrate is required in a case that the remainder obtained by dividing the number of unprocessed substrates U by the number of batch substrates B is a value excluding zero, and in a case that the number of batches N is not more than the number of process chambers M. FIG. 17, FIG. 18 and FIG. 19 show for example the processing based on the algorithms A1, A2, and A3, as a technique of calculating required number of the dummy substrates after the processing of FIG. 16.

FIG. 17 shows a flowchart using the algorithm A1.

In the flow using the algorithm A1, a dummy preferential use order of the process chambers, is decided and the number of substrates is decided so that more numbers of dummy substrates are charged into the process chamber with high preferential order. Namely, the number of unprocessed substrates U is divided by the number of batches N to thereby calculate the remainder (S42-5a), and when the remainder is zero, the value obtained by dividing the number of unprocessed product substrates U by the number of batches N, is set as the number of product substrates P in the batch (S42-10a).

When the remainder is a value excluding zero, dummy substrates preferential use PM decision processing as will be described later is executed, to thereby decide the order of the process chamber in which the dummy substrates are preferentially used (S42-6a).

Next, the process chamber being a charging destination, and the process chamber in which the dummy substrates are preferentially used, are compared (S42-7a), and when both process chambers are matched with each other, the value obtained by dividing the number of unprocessed product substrates U by the number of batches N is set as the number of product substrates P (S42-10a). In a case of mismatch of both process chambers, the value obtained by adding 1 to the value obtained by dividing the number of unprocessed product substrates U by the number of batches N is set as the number of product substrates P in the batch (S42-8a). As described above, the number of product substrates P in the batch is decided.

The number of dummy substrates D in the batch is decided by subtracting the number of product substrates P in the batch decided as described above, from the number of batch substrates B (S42-9a).

FIG. 18 shows a flowchart using the algorithm A2.

In the flow using the algorithm A2, the order of the process chambers in which the dummy substrate is preferentially used, is decided, and based on a technique different from the technique of FIG. 17, the number of substrates is decided so that more numbers of dummy substrates are charged into the process chamber with high preferential order. Namely, the number of unprocessed product substrates U and the number of batch substrates B are compared (S42-5b), and when the number of unprocessed product substrates U is not more than the number of batch substrates B, the number of unprocessed product substrates U is set as the number of product substrates P in the batch (S42-11b).

When the number of unprocessed product substrates U is larger than the number of batch substrates B, the dummy substrate preferential use PM decision processing as will be described later, is executed, to thereby decide the order of the process chambers in which the dummy substrates are preferentially used (S42-6b).

Next, the process chamber being the charging destination, and the process chamber in which the dummy substrates are preferentially used, are compared (S42-7b), and when both process chambers are matched with each other, the number of batch substrates B is subtracted from the number of unprocessed product substrates U, and the value thus obtained is set as the number of product substrates P in the batch (S42-10b). In a case of mismatch of both process chambers, the number of batch substrates B is set as the number of product substrates P in the batch (S42-8b). As described above, the number of product substrates P in the batch is decided.

The number of dummy substrates D in the batch is decided by subtracting the number of product substrates P in the batch decided as described above, from the number of batch substrates B (S42-9b).

FIG. 19 shows a flowchart using the algorithm A3.

In the flow using the algorithm A3, the numbers of charge of the dummy substrates into each process chamber PM1, PM2 are equalized as much as possible. Namely, the number of unprocessed product substrates U is divided by the number of batches N to calculate the remainder (S42-5c), and when the remainder is zero, the value obtained by dividing the unprocessed product substrates U by the number of batches N is set as the number of product substrates P in the batch (S42-10c). When the remainder is a value excluding zero, the value obtained by adding to the value obtained by dividing the number of unprocessed product substrates U by the number of batches N is set as the number of product substrates P (S42-8c). As described above, the number of product substrates P in the batch is decided.

The number of dummy substrates D in the batch is decided by subtracting the number of product substrates P in the batch decided as described above, from the number of batch substrates B (S42-9c).

As described above, the substrate number decision processing based on a prescribed algorithm is ended. Note that the aforementioned algorithms A1, A2, A3 are given as examples, and the algorithm excluding the aforementioned algorithms can also be used, such as differentiating and distributing the number of charging dummy substrates in the batch according to the dummy preferential use PM order for example. Further, a plurality of aforementioned algorithms may be combined and used.

### (Dummy Preferential Use PM Order Decision Processing)

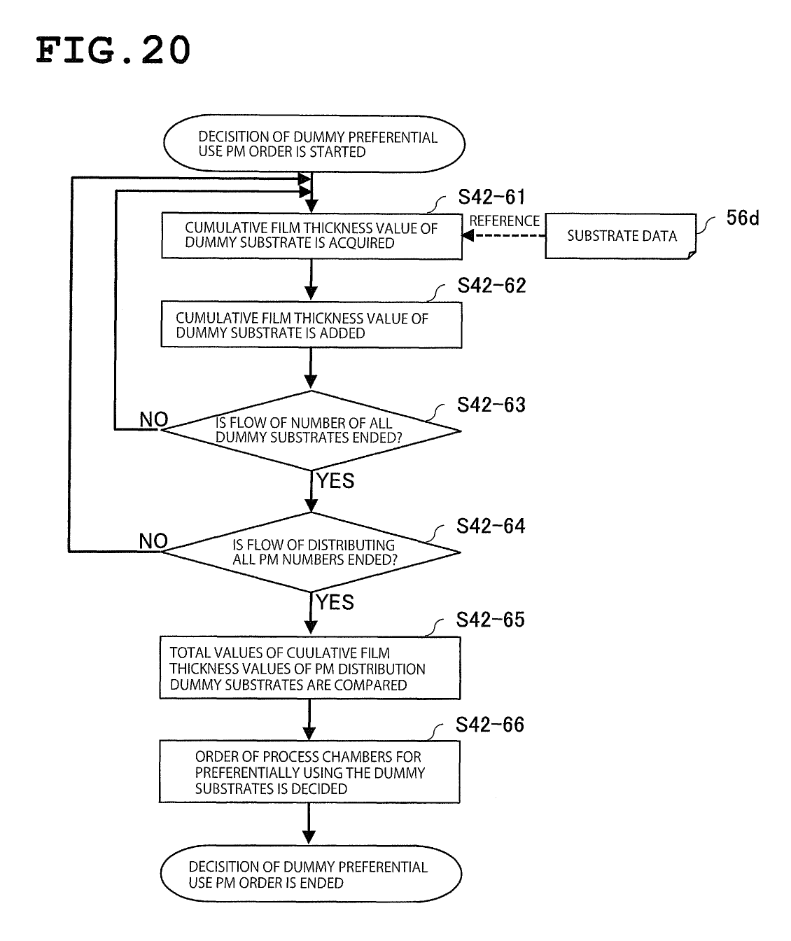

Next, the dummy preferential use PM order decision processing executed in the substrate number decision processing will be described using FIG. 20. FIG. 20 is a flowchart of the dummy preferential use PM order decision processing by the batch assembly unit 54 possessed by the control part 239 according to this embodiment.

As described above, when the batch assembly is performed, the number of product substrates does not satisfy the number of processing product substrates, and the batch into which the dummy substrates are assembled, is fixed to a last batch or a first batch per one processing or one lot. When a plurality of batches thus assembled are sequentially processed in a plurality of process chambers, the process chamber that easily hits the batch including the dummy substrates is generated, thus increasing the frequency of use of the dummy substrates distributed to such a process chamber in some cases.

In this embodiment, as described below, the process chamber in which the dummy substrates are preferentially used, is decided in an order from the process chamber in which a total value of the cumulative film thickness values of the distributed dummy substrates is small. Thus, in the aforementioned substrate number decision processing, more numbers of dummy substrates are distributed to the process chamber with high preferential order, namely the process chamber in which the cumulative film thickness value of the dummy substrates is small and the dummy substrates are not used so much, thus further reducing the deviation in the use state of the dummy substrates in each process chamber PM1, PM2.

A specific dummy preferential use PM order decision technique will be described based on the flowchart of FIG. 20.

As shown in FIG. 20, the batch assembly unit 54 references the substrate data 56d, and sequentially extracts the dummy substrates distributed to a prescribed process chamber (S42-61), and adds the cumulative film thickness value of the dummy substrates (S42-62) to calculate a total value (S42-63). Further, S42-61 to S42-63 are repeated for all process chambers PM1, PM2 to which the dummy substrates can be distributed (S42-64). Next, total values of the cumulative film thickness values of the dummy substrates distributed for each process chamber PM1, PM2 are compared (S42-65), and the process chamber in which the dummy substrates are preferentially used, is decided in an order from a smaller total value (S42-66). In a case of an equal total value, for example the smaller number of the process chamber is preferentially selected (PM1 is selected in a case of PM1 and PM2).

As described above, the dummy preferential use PM order decision processing is ended.

As described above, the batch assembly unit 54 executes the aforementioned batch assembly processing based on the dummy preferential use PM order, every time the group object is delivered from the group controller 53 that repeats the batch start processing and the batch charge processing, to thereby sequentially charge the substrates W in each batch.

Note that the PM average film thickness value of each process chamber is obtained in the same procedure as described above, and when all PM average film thickness values are the same, the dummy preferential use PM order may be decided by the number of the dummy substrates (frequency of use of the dummy substrates) in each process chamber. Thus, when the number of dummy substrates is decided in the aforementioned substrate number decision processing, the value obtained by dividing the average film thickness values of the deposited film formed per one processing, by the number of the decided dummy substrates, can be approximately the same value in the process chambers PM1 and PM2. Therefore, the cumulative film thickness values of the dummy substrates in each process chamber can be made to be even to be approximately the same value.

### (11) Batch Charge Processing

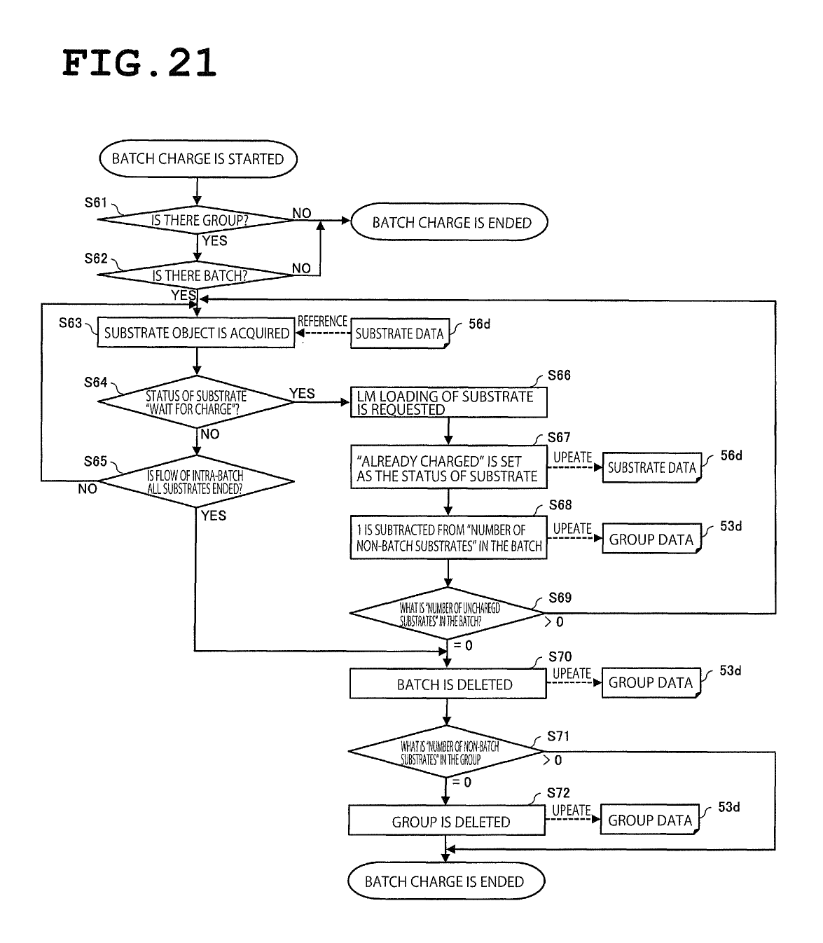

Next, the flow of the batch charge processing will be described using FIG. 21. FIG. 21 is a flowchart of the batch charge processing by the group controller 53 possessed by the control part 239 according to this embodiment.

In the batch charge processing, the substrates W in the second round or thereafter in the batch started by the batch start request, are sequentially charged into the substrate processing apparatus 10 until the transfer of all substrates W in the batch is ended.

Namely, as shown in FIG. 21, the group controller judges presence/absence of the group object, with reference to the group data 53d (S61). When there is no group object, the batch charge processing is ended. When there is the group object, the group controller 53 judges whether or not the batch object is associated with the group object, with reference to the substrate data 56d of the batch object acquired from the batch assembly unit 54 (S62). When the group object is not associated with the batch object, the batch charge processing is ended. When the group object is associated with the batch object, the substrate data 56d of the batch object is referenced, and the substrate object of the head of the substrate list is acquired (S63), and whether the status of the substrate object is set in the “wait for charge” is judged (S64). When the status is set in the “wait for charge”, the next substrate object in the substrate list is referenced, and the judgment is repeated until reference of all substrate objects in the batch object is ended (S65).

When the status is set in the “wait for charge”, the loading request is given to the load lock chambers LM1, LM2, regarding the substrates W corresponding to the substrate object having such a status (S66). Further, “already charged” is set in the status of the substrate object, to update the substrate data 56d (S67). Next, the group data 53d is referenced, and the value obtained by subtracting one from the value of the “number of non-charged substrates” in the batch of the group object, is set as the “number of non-charged substrates”, to update the group data 53d (S68). After update, whether or not the “number of non-charged substrates” is zero is judged (S69), and when it is larger than zero, the processing after S63 is repeated.

When the “number of non-charged substrates” after update is zero, association between the batch object and the group object of this batch object is canceled, and the group data 53d is updated (S70). Further, whether or not the “number of non-batch substrates” of the group object is zero, is judged (S71), and when it is zero, the group object is canceled and the group data 53d is updated (S72). When the “number of non-batch substrates” is larger than zero, the group object is not canceled, and the batch charge processing is ended.

As described above, the batch charge processing is ended. As described above, when transfer of all substrates W in the batch is ended to end the batch charge processing, the group controller 53 executes the batch start request again, to start the charge of the next batch. Thus, the batch start request processing and the batch charge processing are repeated, to execute the transfer of all batches.

### (12) PM Status Update Processing and Dummy Substrate Status Update Processing

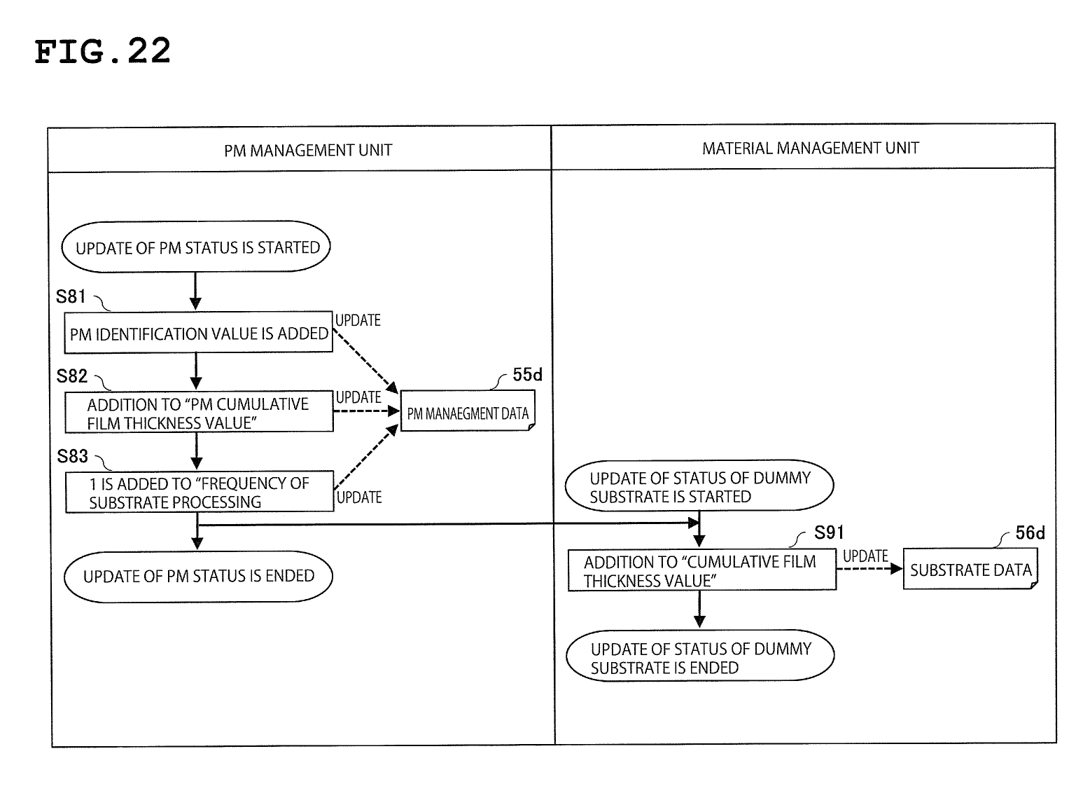

Next, each flow of PM status update processing and dummy substrate status update processing will be described using FIG. 22. FIG. 22 is a flowchart of the PM status update processing by the PM management unit 55, and the dummy substrate status update processing by the material management unit 56 possessed by the control part 239 according to this embodiment.

In the PM status update processing, the status of the cumulative film thickness value, etc., in the process chamber is updated, when the substrate processing in a prescribed process chamber is ended. In the dummy substrate status update processing, the cumulative film thickness value of the used dummy substrate is updated.

Namely, as shown in FIG. 22, the PM management unit 55 adds an identification value of the process chamber in which the substrate processing of the currently execution group is ended, to the end of a PM charge order list, and the PM management data 55d is updated (S81). Further, the PM management unit 55 adds a film thickness value in the current substrate processing to the “PM cumulative film thickness value” of the process chamber (S82), and adds one to the “frequency of substrate processing” (S83), and the PM management data 55d is updated. Further, the current film thickness value is delivered to the material management unit 56.

When there is the dummy substrates used in the current substrate processing, the film thickness value delivered from the PM management unit 55 is added to the “cumulative film thickness value” of the dummy substrate object of all used dummy substrates, and the substrate data 56d is updated (S91).

As described above, the PM status update processing and the dummy substrate status update processing are ended.

(13) Effect of this Embodiment

According to this embodiment, one or a plurality of following effects are exhibited.

(a) According to this embodiment, the control part 239 provided in the substrate processing apparatus 10 decides the number of dummy substrates used in each process chamber PM1, PM2, so that the number of substrates in each process chamber PM1, PM2 reaches a prescribed number.

In the aforementioned structure, the control part 239 performs control so that each type of substrate is distributed to each process chamber PM1, PM2, and the number of dummy substrates used in each process chamber PM1, PM2 reaches approximately the same number between the process chambers PM1 and PM2 per final one processing in the process chambers PM1, PM2.

Further, in the aforementioned structure, the control part 239 performs control so that each type of substrate is distributed to each process chamber PM1, PM2, and when lot processing is performed continuously, the total values of the cumulative film thickness values of the dummy substrates are compared in each lot processing, and as a result, the dummy substrates are distributed to the process chamber in which the total value is small, so that the dummy substrates are used equally in each process chamber PM1, PM2.

As described above, the deviation in the use state of the dummy substrates in each process chamber PM1, PM2 is reduced, and the use efficiency of the dummy substrates can be improved.

(b) Further, according to this embodiment, the control part 239 provided in the substrate processing apparatus 10, distributes the number of dummy substrates used in each process chamber PM1, PM2. Thus, the deviation in the use state of the dummy substrates in each process chamber PM1, PM2 is reduced, and the use efficiency of the dummy substrate can be improved. Particularly, when at least one lot is subjected to distribution processing in the process chambers PM1, PM2, the number of dummy substrates distributed to the process chamber can be set to approximately the same number in each process chamber PM, in the last processing of lot. In the distribution processing, basically the same processing is executed in each process chamber PM, and therefore it is important to adjust the number of dummy substrates to the same number at minimum. Further, according to this embodiment, when at least one lot is subjected to distribution processing in the process chambers PM1, PM2, the number of dummy substrates is distributed so that the value obtained by dividing an integrated value of the deposited film formed in the process chamber by the number of distributed dummy substrates, is approximately the same value in each process chamber PM1 and PM2, per one processing in a prescribed process chamber. Thus, the cumulative film thickness values of the dummy substrates in each process chamber PM1, PM2 is approximately the same value, and the use state of the dummy substrates can be made even to the same degree. Further, in the final processing of the lot, the number of dummy substrates is distributed to each process chamber PM1, PM2 per one processing in a prescribed process chamber, so that the value obtained by integrating film thickness values of the deposited film of the dummy substrates used in the process chamber by the number of the distributed dummy substrates, is approximately the same value between the process chambers PM1 and PM2. Therefore, improvement of the use efficiency and reduction of the frequency of use of the dummy substrates are achieved in the whole body of the dummy substrates, and a consumption of the dummy substrates is suppressed and the frequency of exchange of the dummy substrates is reduced, to thereby realize cost reduction.
(c) Further, according to the aforementioned structure of this embodiment, the dummy substrates are not shared between the process chambers PM1 and PM2 in which contents of the substrate processing are different from each other, and therefore characteristic variation of the substrate processing can be suppressed. Further, diffusion of particles between the process chamber in which a plurality of particles are generated due to some factor, and the other process chamber, can be suppressed.
(d) Further, according to this embodiment, when at least two lots are continuously subjected to distribution processing in the process chambers PM1 and PM2, the number of dummy substrates is distributed to each process chamber PM1, PM2 per one processing in a prescribed process chamber, so that the value obtained by dividing the cumulative integrated value of the deposited film formed in the process chamber by the cumulative number of the distributed dummy substrates, is approximately the same value between the process chambers PM1 and PM2. Thus, the cumulative film thickness value of the dummy substrates in each process chamber PM1, PM2 is approximately the same value, and the use state of the dummy substrate can be made even to the same degree. Further, in the last processing of the lot, the number of dummy substrates is distributed to each process chamber PM1, PM2 per one processing in a prescribed process chamber, so that the cumulative value obtained by integrating film thickness values of the deposited film of the dummy substrates used in the process chamber, by the number of the distributed dummy substrates, is approximately the same value between the process chambers PM1 and PM2. Therefore, the improvement of the use efficiency and the reduction of the frequency of use of the dummy substrates are achieved in the whole body of the dummy substrates, and the consumption of the dummy substrates is suppressed and the frequency of exchange of the dummy substrates is reduced, to thereby realize the cost reduction.
(e) Further, according to this embodiment, the control part 239 processes a plurality of substrates W by combining the product substrates and the dummy substrates. At this time, when different processing is applied to the substrates W in each process chamber PM1, PM2, the control part 239 performs control so that the substrates W are distributed to each process chamber PM1, PM2, and the whole body of the dummy substrates combined with the product substrates can be equally used. Thus, the deviation in the use state of the dummy substrates due to the difference of the substrate processing in each process chamber PM1, PM2, can be reduced.
(f) Further, according to this embodiment, even in a case of a different lot of the product substrates, the control part 239 performs control to collectively process the product substrates in one process chamber. Thus, the frequency of adjustment of the number of substrates in each lot by the dummy substrates, can be reduced. Therefore, the frequency of use of the dummy substrates can be reduced.
(g) Further, according to this embodiment, collective processing of the product substrates in the aforementioned different lot, can be applied to the substrate processing apparatus including at least one process chamber. Namely, when the number of the product substrates does not reach the prescribed number that can be processed when the last product substrate of a prescribed lot is disposed at a prescribed position in the process chamber, the same process chamber is replenished with the product substrates by loading the product substrates of the next lot into the process chamber, thus achieving collective processing. At this time, the sequence recipe of each lot is the same.
(h) Further, according to this embodiment, when the product substrates are combined with the dummy substrates, the dummy substrates are combined with the product substrates designated by a different job having the same sequence recipe, and the substrates are simultaneously processed in the process chambers PM1, PM2. Thus, the frequency of adjustment of the number of dummy substrates for each job can be reduced. Therefore, the frequency of use of the dummy substrates can be reduced.
(i) Further, according to this embodiment, the reduction of the frequency of adjustment of the number of dummy substrates for each job, can also be realized by combining the product substrates and the dummy substrates for each group unit having the same job, and processing the substrates in the process chamber sequentially for each group unit.
(j) Further, according to this embodiment, the batch assembly unit 54 designates the dummy substrates to be used in the same process chamber, in an order from a smaller cumulative film thickness value. Thus, the deviation in the use state of the dummy substrates in the same process chamber can be reduced, and the use efficiency of the dummy substrates can be improved.
(k) Further, according to this embodiment, the batch assembly unit 54 decides an order of the process chambers in which the dummy substrate is preferentially used, in an order from the process chamber in which the total value of the cumulative film thickness values of the distributed dummy substrates is small. Thus, the deviation in the use state of the dummy substrates in each process chamber PM1, PM2 can be further reduced. (1) Further, according to this embodiment, the control part 239 provided in the substrate processing apparatus 10 decides the number of dummy substrates used in each process chamber PM1, PM2, so that the number of substrates in the process chambers PM1, PM2 is a prescribed number. With this structure, the deviation in use of the dummy substrates can be eliminated, even if the lot processing is not continuous and there is an idling time between a lot A and a lot B. Further, even when the sequence recipes used in the lot A and the lot B are different from each other, use of the dummy substrates in each lot is adjusted, and therefore the deviation in use of the dummy substrates can be eliminated. In this structure, the control part 239 may decide the number of substrates so that an average film thickness value obtained by dividing the deposited film formed per one processing in the process chambers PM1, PM2 by the number of dummy substrates decided in each process chamber PM1, PM2, is approximately the same value between the process chambers PM1 and PM2.

### EXAMPLES

### (1) Intra-Lot Processing Based on Different Sequence Recipe

In the substrate processing apparatus according to examples 1, 2 of the present invention and comparative example 1, explanation will be given for a case that intra-lot processing based on a different sequence recipe is applied to one lot of a carrier cassette in which twenty-three product substrates are stored.

Similarly to the aforementioned substrate processing apparatus 10, the substrate processing apparatus according to examples 1 and 2 includes two process chambers PM1a, PM2a in which the number of substrates is five respectively, and process chambers PM1b, PM2b respectively. Further, similarly to the aforementioned control part 239, the substrate processing apparatus of examples 1, 2 has a control part for performing dummy preferential use PM order decision processing. Further, the control part of example 1 performs substrate number decision processing based on the algorithm A1, and the control part of example 2 performs substrate number decision processing based on the algorithm A2.

In the same way as described above, the substrate processing apparatus according to comparative example 1 includes two process chambers PM1c and PM2C in which the number of substrates per 1 batch is five respectively. Further, the substrate processing apparatus of comparative example 1 includes a control part for processing a plurality of batches in an order from a smaller number of the process chamber.

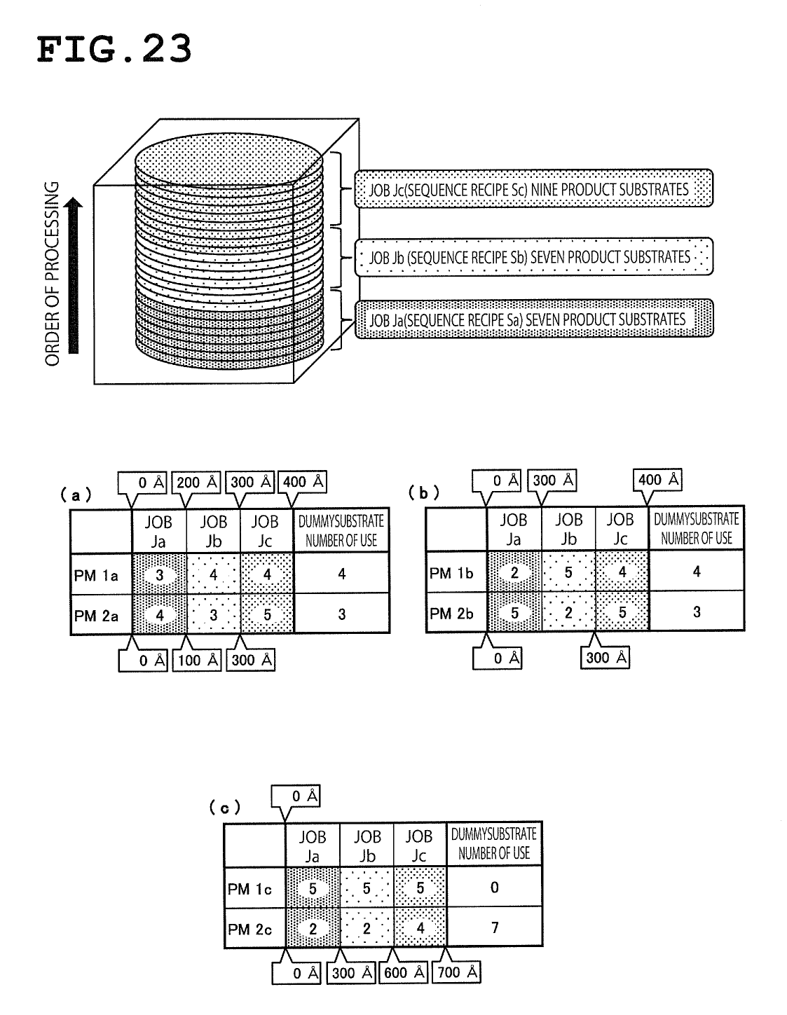

As a more specific processing condition, twenty-three product substrates are stored in the carrier cassette as shown in FIG. 23, and job Ja having a sequence recipe Sa is distributed to seven product substrates out of these twenty-three product substrates, job Jb having a sequence recipe Sb is distributed to other seven product substrates, and job Jc having a sequence recipe Sc is distributed to the remaining nine product substrates.

Any one of the sequence recipes Sa, Sb, and Sc are the sequence recipes of distribution processing for designating two process chambers according to each example and comparative example. Further, in any one of the sequence recipes Sa, Sb, and Sc, the film thickness value of the deposited film formed in each process chamber by one substrate processing, is 100 Å. The total value of the cumulative film thickness values of the dummy substrates distributed to each process chamber, is 0 Å at an initial value. Each job Ja, Jb, and Jc are executed in an order of production, and is executed in an order of job Ja, Jb, and Jc.

Under the aforementioned condition, FIG. 23A and FIG. 23B show a breakdown of the number of product substrates in each batch in a case of applying intra-lot processing to the twenty-three product substrates by the substrate processing apparatus of examples 1 and 2, and the total value of the cumulative film thickness values of the used dummy substrates, respectively.

As shown in FIG. 23A, in the substrate processing apparatus according to example 1, the batch assembly processing is performed for each job Ja, Jb, and Jc, and above all, the dummy preferential use PM order decision processing is performed. In job Ja, the total value of the cumulative film thickness values of the dummy substrates is 0 Å and is equal between both process chambers PM1a and PM2a, and therefore the process chamber PM1a of a smaller number is designated as the process chamber in which the dummy substrates are most preferentially used. Therefore, based on the algorithm A1, the batch assembly of three product substrates+two dummy substrates is performed to the process chamber PM1a, and the batch assembly of four product substrates+one dummy substrate is performed to the process chamber PM2a. The total value of the cumulative film thickness values of the dummy substrates after executing the job Ja, is 200 Å and 100 Å respectively in the process chamber PM1a and the process chamber PM2a.

In the job Jb, the process chamber PM2a in which the total value of the cumulative film thickness values of the dummy substrates is small, is designated as the process chamber of a most preferential use of the dummy substrates, and the batch assembly and the processing are performed respectively based on the job Jb. In the job Jc, the total value of the cumulative film thickness values of the dummy substrates is 300 Å which is equal again between the process chambers, and therefore the process chamber PM1a of a smaller number is used as the most preferential use process chamber, in which processing is performed respectively.

Further, as shown in FIG. 23(b), in the substrate processing apparatus according to example 2, the dummy preferential use PM order decision processing is performed by a similar procedure as the case of example 1, wherein the batch assembly is performed using the algorithm A2, and each of the jobs Ja, Jb, and Jc is executed.

After the aforementioned substrate processing, the number of use of the dummy substrates is four and the total value of the cumulative film thickness values is 400 Å in process chambers PM1a and 1b. Meanwhile, the number of use of the dummy substrates is three and the total value of the cumulative film thickness values is 300 Å in process chambers PM2a, 2b. Thus, in the substrate processing apparatus according to examples 1, 2, the number of the use of the dummy substrates and the total value of the cumulative film thickness values can be made even to approximately an equal value between the process chambers.

Under a similar condition as described above, FIG. 23C shows the breakdown of the number of product substrates in each batch, and the total value of the cumulative film thickness values of the used dummy substrates, in a case of applying the intra-lot processing to the aforementioned twenty-three product substrates, in the substrate processing apparatus of comparative example 1.

As shown in FIG. 23C, in the substrate processing apparatus according to comparative example 1, the number of use of the dummy substrates in the process chamber PM1c is zero, the total value of the cumulative film thickness values is 0 Å, the number of use of the dummy substrates in the process chamber PM2c is seven, and the total value of the cumulative film thickness values is 700 Å. Thus, in the substrate processing apparatus according to comparative example 1, a plurality of batches are processed in an order from the smaller number of the process chamber, resulting in a deviated use of the dummy substrates distributed to the process chamber PM2c.

### (2) Multiple Lots Processing Based on a Different Sequence Recipe

Next, similarly as described above, explanation will be given for a case that processing is applied to multiple lots to which jobs having different sequences are respectively distributed, in the substrate processing apparatus (having the same structure as described above) according to examples 1, 2, and comparative example 1.

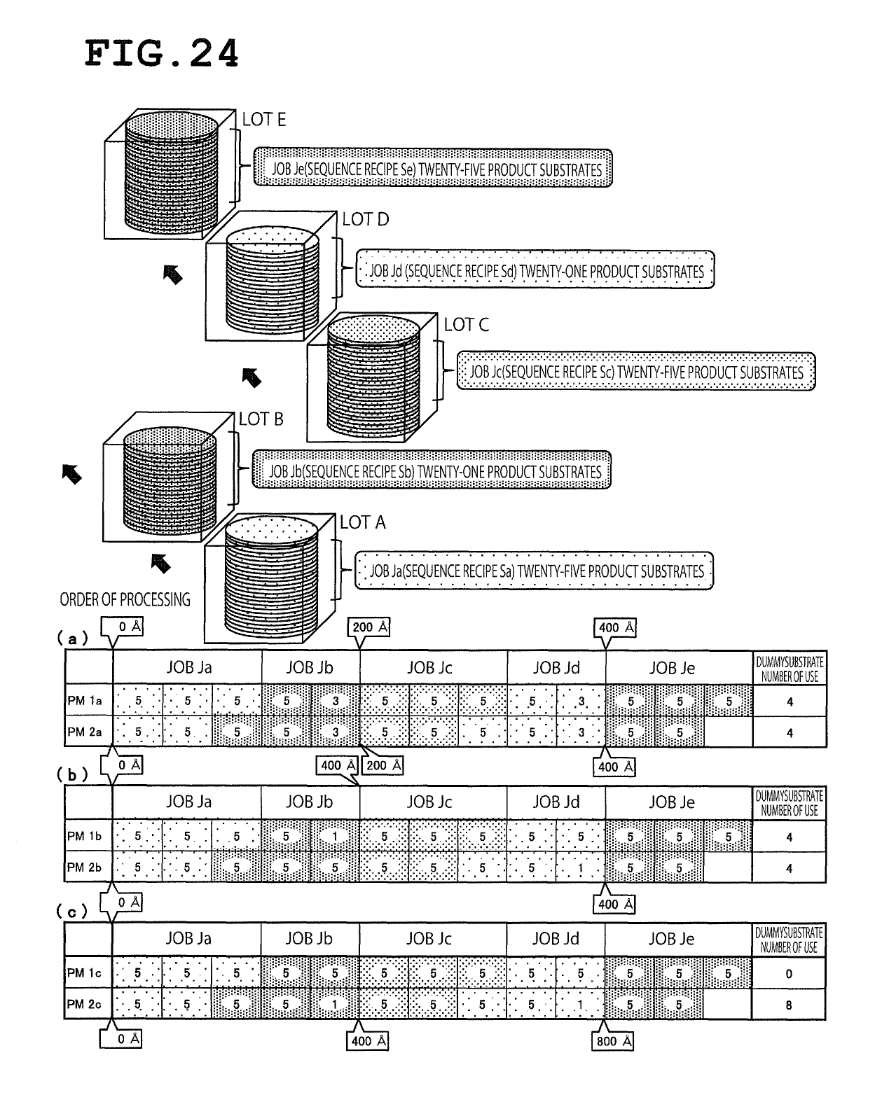

As a more specific processing condition, as shown in FIG. 24, lot A storing twenty-five product substrates, lot B storing twenty-one product substrates, lot C storing twenty-five product substrates, lot D storing twenty-one product substrates, and lot E storing twenty-five product substrates, are sequentially charged into the carrier cassette. The job is different for each lot, and specifically job Ja having sequence recipe Sa, job Jb having sequence recipe Sb, jog Jc having sequence recipe Sc, job Jd having sequence recipe Sd, and job Je having sequence recipe Se, are distributed to the product substrates of lots A, B, C, D, and E.

Any one of the sequence recipes Sa, Sb, and Sc is the sequence recipe for the distribution processing, and the film thickness value of the deposited film per one substrate processing is 100 Å. The total value of the cumulative film thickness values of the dummy substrates is 0 Å at the initial value. Each job is executed in an order of jobs Ja, Jb, Jc, Jd, and Je.

Under the condition as described above, FIG. 24A and FIG. 24B show the breakdown of the number of product substrates in each batch in a case of performing the processing of multiple lots A, B, C, D, E, and the total value of the cumulative film thickness values of the used dummy substrates, in the substrate processing apparatus according to examples 1 and 2.

As shown in FIG. 24A and FIG. 24B, the number adjustment by the dummy substrates is performed in both substrate processing apparatuses of examples 1 and 2, based on the algorithms A1, A2 respectively in the jobs Jb, Jd distributed to lots B, D in which the number of products substrates is insufficient. Asa result, it is found that in both substrate processing apparatuses of examples 1 and 2, the number of used dummy substrates in process chambers PM1a, 1b is four, the total value of the cumulative film thickness values is 400 Å, the number of used dummy substrates in process chambers PM2a, 2b is four, and the total value of the cumulative film thickness values is 400 Å. Thus, in the substrate processing apparatuses of examples 1, 2, the number of used dummy substrates and the total value of the cumulative film thickness values can be made even between the process chambers, even in a case of multiple lots processing based on different sequence recipes.

Under the similar condition as described above, FIG. 24C shows the breakdown of the number of product substrates in each batch in a case of performing the processing of multiple lots A, B, C, D, E, and the total value of the cumulative film thickness values of the used dummy substrates.

As shown in FIG. 24C, in the substrate processing apparatus according to comparative example 1, the number of use of the dummy substrates is zero and the total value of the cumulative film thickness value is 0 Å in the process chamber PM1c, and the number of use of the dummy substrates is eight and the total value of the cumulative film thickness values is 800 Å in the process chamber PM2c. Thus, in the substrate processing apparatus according to comparative example 1, there is a deviated use of the dummy substrates distributed to the process chamber PM2c, even in a case of multiple lots processing based on different sequence recipes.

### (3) Multiple Lots Processing Based on the Same Sequence Recipe

Subsequently, explanation will be given for a case of performing multiple lots processing to which the job based on the same recipe is distributed, in the substrate processing apparatuses of example 3 and comparative example 2.

Similarly to the aforementioned substrate processing apparatus 10, the substrate processing apparatus according to example 3 includes two process chambers PM1d and PM2d in which the number of substrates in one batch is five respectively, and further includes a control part for performing grouping processing for each job based on the same sequence recipe similarly to the aforementioned control part 239.

Similarly as described above, the substrate processing apparatus according to comparative example 2 includes two process chambers PM1e and PM2e in which the number of substrates in one batch is five respectively, and further includes the control part for performing processing for each different job in an order from the smaller number of the process chamber.

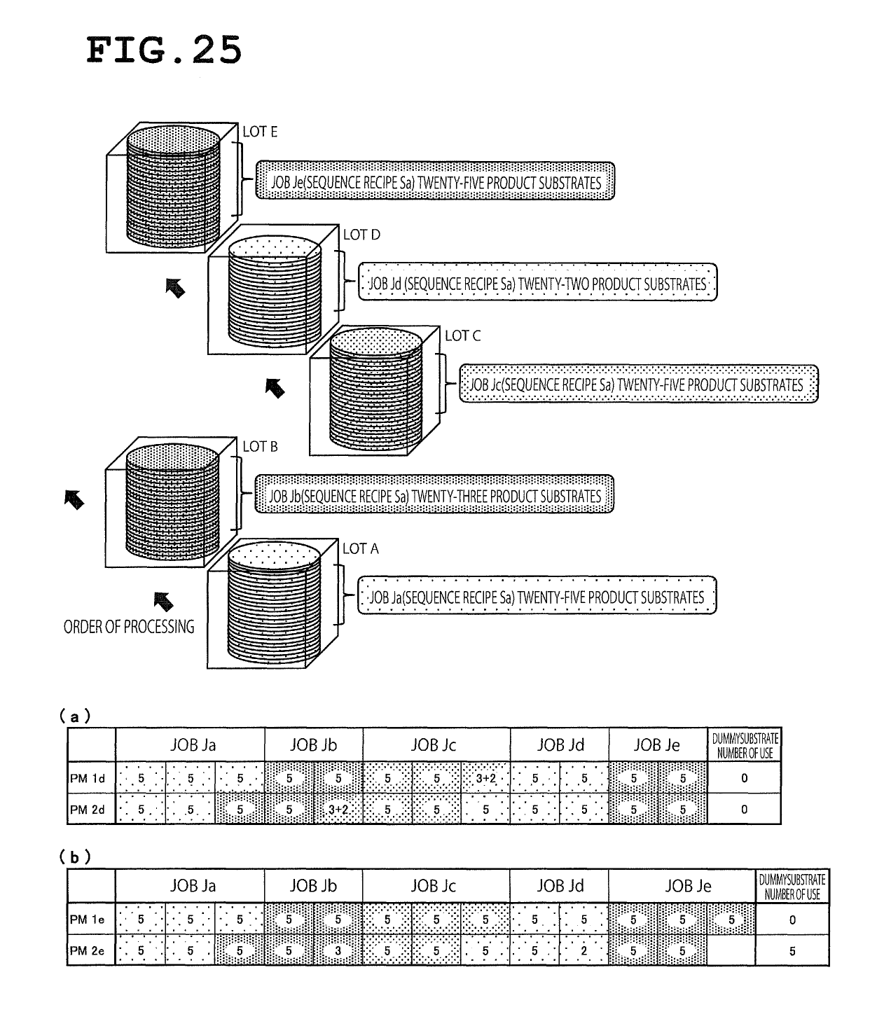

As a more specific condition, as shown in FIG. 25, jobs Ja, Jb, Jc, Jd, Je having the same sequence recipe Sa are respectively distributed to the lot A including twenty-five product substrates, the lot B including twenty-three product substrates, the lot C including twenty-five product substrates, the lot D including twenty-two product substrates, and the lot E including twenty-five product substrates. The sequence recipe Sa is the sequence recipe for the distribution processing, and each job is executed in an order of the jobs Ja, Jb, Jc, Jd, and Je.

Under the aforementioned condition, FIG. 25A and

FIG. 25B show the breakdown of the number of product substrates in each batch in a case of applying processing to multiple lots A, B, C, D, E by the substrate processing apparatus according to example 3.

As shown in FIG. 25A, in the substrate processing apparatus according to example 3, grouping with job Jc distributed to the lot C between the lots B and D, is performed in the jobs Jb, Jd distributed to the lots B and D in which the number of product substrates in the lot is insufficient. As a result, in the substrate processing apparatus according to example 3, the number of use of the dummy substrates in the process chambers PM1d and PM2d is zero. Thus, in the substrate processing apparatus according to example 3, processing is collectively performed in the process chamber even if the lot of the product substrate is different, and the processing can be applied to multiple lots without using the dummy substrates.

Under the similar condition as described above, FIG. 25B shows the breakdown of the number of product substrates in each batch in a case of performing the processing of multiple lots A, B, C, D, E by the substrate processing apparatus according to comparative example 2.

As shown in FIG. 25B, in the substrate processing apparatus according to comparative example 2, the number of use of the dummy substrates in the process chamber PM1e is zero, and the number of use of the dummy substrates in the process chamber PM2e is five. Thus, in the substrate processing apparatus according to comparative example 2, lots to which different jobs are distributed, cannot be batch-assembled even if the jobs having the same sequence recipe are continuous, thereby increasing the frequency of use of the dummy substrates. Further, the substrate processing apparatus according to comparative example 2 results in a deviated use of the dummy substrates distributed to the process chamber PM2e.

### Other Example

As described above, mainly in a case that the substrate processing is applied to multiple lots continuously (when the job is executed), the dummy substrates can be efficiently used, and the substrate processing without dummy substrates can be realized. However, it is not always true that multiple lots are continuously processed. For example, there is a possibility that idling time is generated between the lot A and the lot B. In this case, the following structure is desirable. Namely, it is preferable that either the process chamber PM1 or the PM2 can be selected for starting the substrate processing according to the number of lots A and lots B. Note that in this embodiment (other example), an apparatus structure and a controller structure (the structure of the controller 239) are the same as those of example 1 to example 3 of the present invention, and therefore detailed description thereof is omitted.

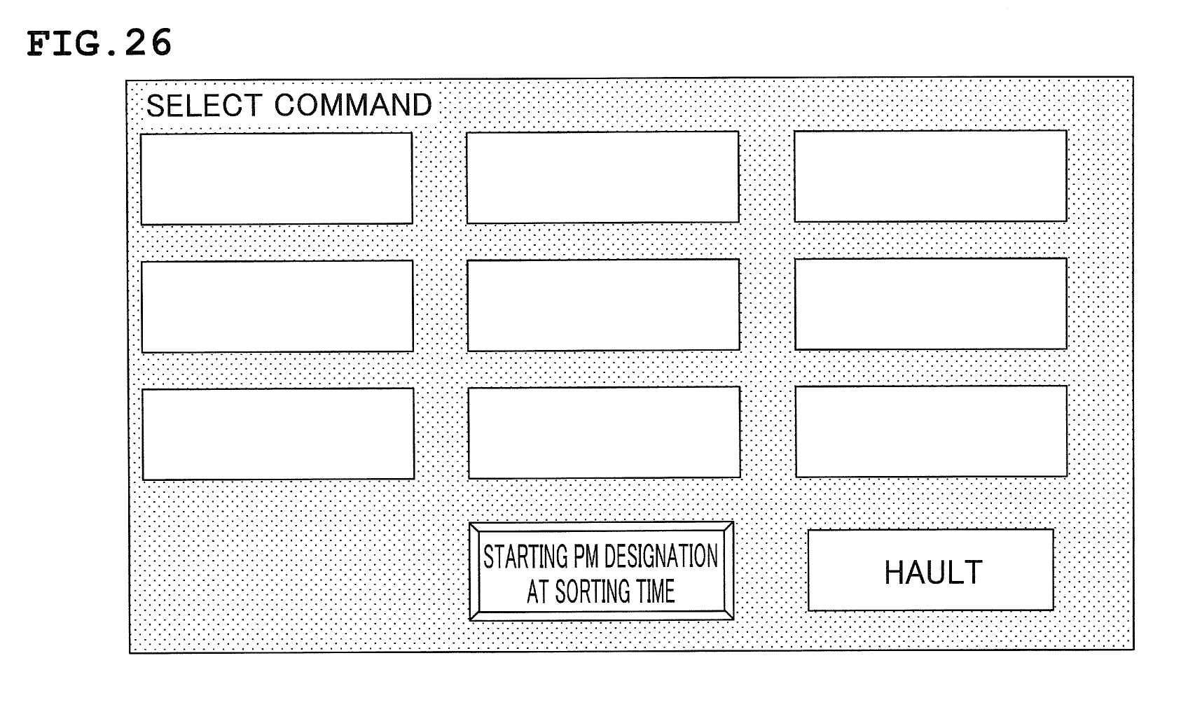

Namely, this embodiment is characterized in that a position is changed for starting the substrate processing by an operator, and the state after change can be confirmed. Explanation will be given hereafter using FIG. 26 to FIG. 28.

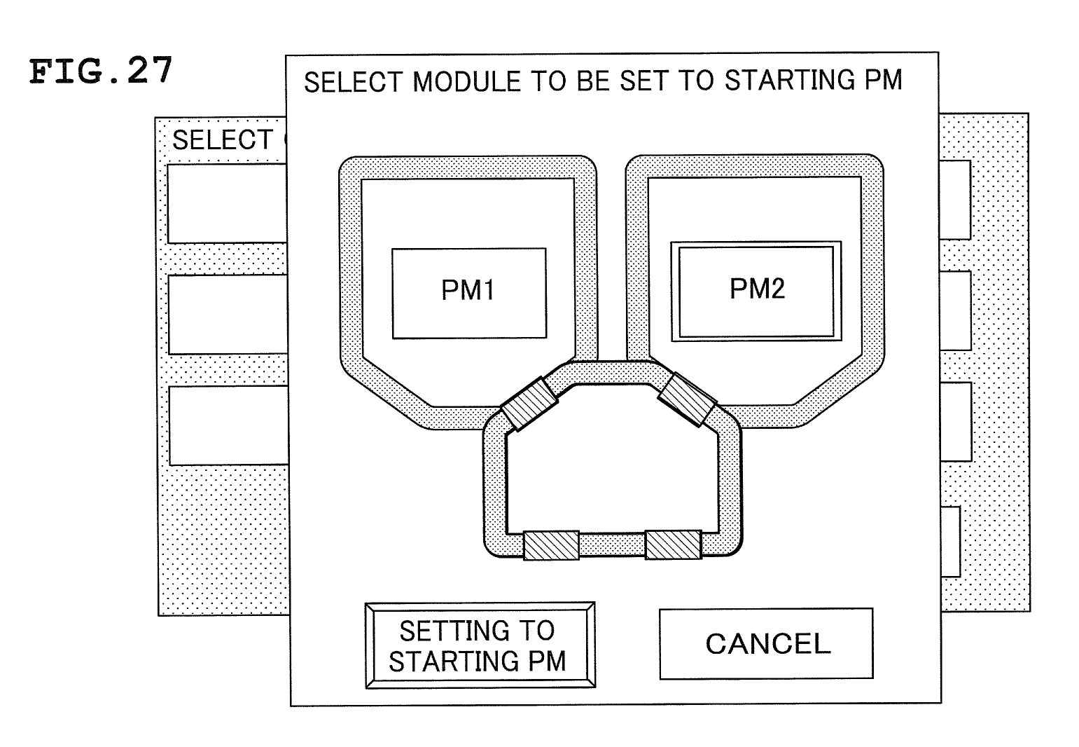

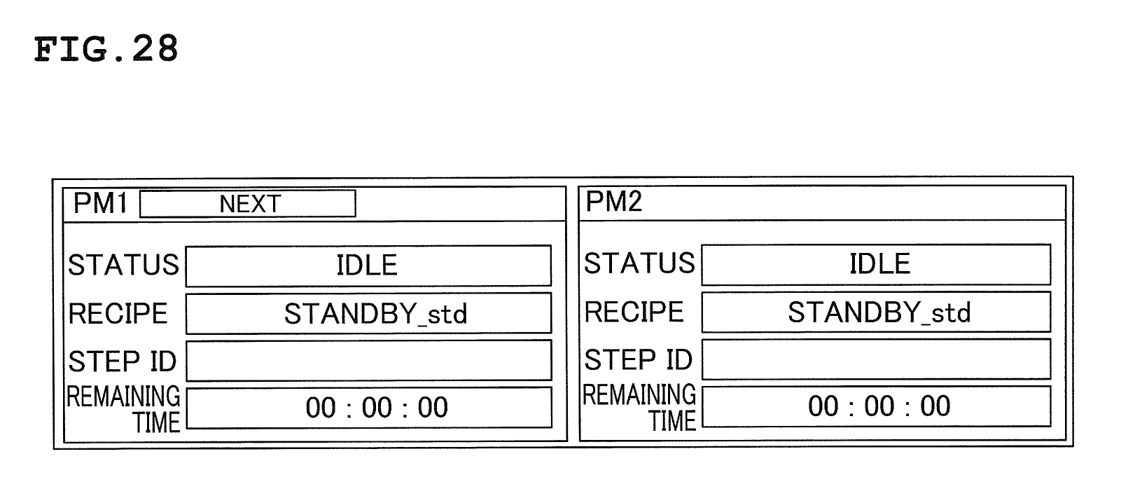

FIG. 26 shows an example of a screen for selecting a prescribed command, FIG. 27 shows an example of a screen for selecting the process chambers PM1 and PM2 for starting the substrate processing, and FIG. 28 shows an example of a screen for displaying the process chambers PM1 and PM2 for starting the substrate processing next.

The operator presses a “system command” button on a title panel, to thereby display a system command selection screen shown in FIG. 26. Next, the operator presses a “distribution time starting PM command” button, to thereby display a starting PM selection screen, and then selects either “PM1” button or “PM2” button, and presses a “starting PM setting” button, to thereby confirm the process chamber PM1 or PM2 to be started at the time of starting the substrate processing.

When the “starting PM setting” is pressed, “NEXT” is displayed for the process chamber PM1 in which the substrate processing is started as shown in FIG. 28 for example.

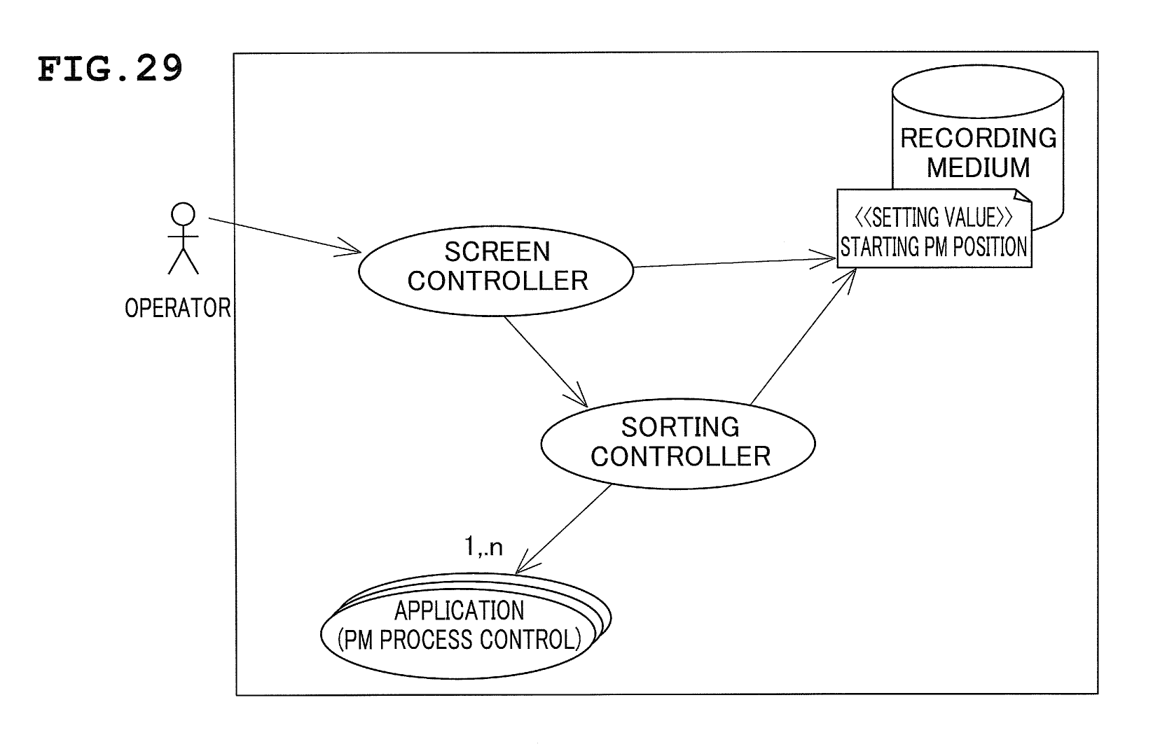

FIG. 29 is a view of a functional structure realized by the controller 239 according to this embodiment. Data processing (flow) will be described hereafter, using FIG. 29.

When a prescribed command is received by pressing the “starting PM setting” button by the operator, a distribution controller is notified of the prescribed command (command showing PM for starting the substrate processing), and refers to a set value (starting PM position), and displays “NEXT” on a prescribed screen.

When a command (showing the starting PM position) is received from the screen controller by main processing for executing the aforementioned function, the distribution controller updates the set value stored in a storage medium being a storage part. The updated set value is referenced when a processing request is given, so that a start command of the process is given to an application (such as a process recipe) including the designated start position.

### A Specific Example of Other Example

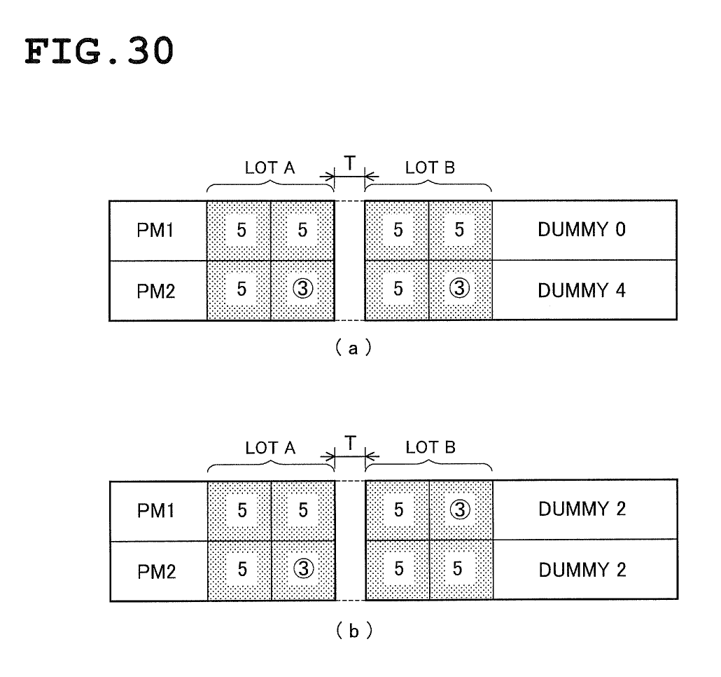

Next, a specific example will be described using FIG. 30. FIG. 30 shows a case that the number of lots A is eighteen, the number of lots B is eighteen, and the lots A and the lots B are not continuously executed, but are executed with idling time T interposed between them.

When processing of the lots A is ended, the process chamber PM1 starts the substrate processing. However, when the processing is started in the process chamber PM1, the dummy substrate is processed only in the process chamber PM2, and therefore the deviation is generated in the use state of the dummy substrate. Therefore, according to this embodiment, after the end of the processing of the lots A, the process chamber into which the substrate being an object to be processed is charged, can be changed to PM2 from PM1. Therefore, when the processing of the lots B is started, the process chamber PM can be selected, for starting the processing of lots by the operator.

Therefore, according to this embodiment, the dummy substrates can be equally distributed to the process chambers PM1 and PM2, and the dummy substrates can be equally used as much as possible. Thus, the deviation in the use state of the dummy substrates in each process chamber PM1, PM2 can be reduced.

In this embodiment, the PM position being a next starting position by the operator can be exactly grasped, and the process starting position can be freely changed as needed, thus contributing to reproducibility of the process and a resulting yield rate.

### Other Embodiment of the Present Invention

As described above, embodiments of the present invention have been specifically described. However, the present invention is not limited to the aforementioned embodiments, and can be variously modified in a range not departing from the gist of the present invention.

For example, in the aforementioned embodiments, explanation is given for a case that the content of the substrate processing by the substrate processing apparatus 10 is mainly the film formation processing. However, the content of the substrate processing is not limited thereto, and may be the etching processing, etc. When the substrate processing is the etching processing, the process chamber and the dummy substrates can be managed by a film thickness value, etc., which is cumulatively etched and removed.

Thus, the present invention can be applied not only to a case that processing is performed to form various films such as an oxide film and a nitride film, and a metal film, but also to a case of performing other substrate processing such as etching, diffusing, annealing, oxidizing, and nitriding, and further can be applied to a case that the dummy substrate is used for not only the substrate processing but also cleaning and conditioning in a process furnace 202, and further can be applied to other substrate processing apparatus such as an etching apparatus, an annealing apparatus, an oxidizing apparatus, a nitriding apparatus, a coating apparatus, a drying apparatus, and a heating apparatus, in addition to a thin film forming apparatus.

Further, the present invention is not limited to a semiconductor manufacturing apparatus, etc., like the substrate processing apparatus 10 of this embodiment for processing the substrate such as a semiconductor wafer, and can be applied to the substrate processing apparatus such as LCD (Liquid Crystal Display) manufacturing apparatus for processing a glass substrate.

Further, the present invention is not limited to a case that the control part 239 is disposed in the substrate processing apparatus 10. For example, it is also acceptable that a main body of the substrate processing apparatus 10 is disposed in a clean room, and at least a part of the control part is disposed in an office (on a floor different from the clean room), so that a state of the substrate processing apparatus 10 is remotely monitored and analyzed.

### Preferred Embodiment of the Present Invention

Preferred embodiments of the present invention will be supplementarily described hereafter.

According to an aspect of the present invention, there is provided a substrate processing apparatus including a plurality of process chambers to process each type of prescribed number of substrates; and a controller configured to perform control to decide the number of dummy substrates used in each process chamber so that the number of substrates in each process chamber reaches a prescribed number and the dummy substrates are used equally.

Preferably, when the number of the dummy substrates is decided so that the number of substrates in each process chamber reaches the prescribed number in performing processing by distributing each type of the substrates to each process chamber, the controller performs control so that the number of the dummy substrates used in each process chamber per last one processing in the process chamber, is approximately the same value in each process chamber.

Preferably, when the number of the dummy substrates is decided so that the number of substrates in each process chamber reaches the prescribed number in performing processing by distributing each type of the substrates to each process chamber, the controller performs control to decide the number of the dummy substrates so that a value obtained by dividing an integrated value of a deposited film formed on the dummy substrates by the number of the dummy substrates, is approximately the same value in each process chamber, per one processing in each process chamber.

Preferably, when the number of the dummy substrates is decided so that the number of substrates in each process chamber reaches the prescribed number in performing processing by distributing each type of the substrates to each process chamber, the controller performs control to decide the number of the dummy substrates so that a value obtained by integrating a deposited film formed in the process chamber by the number of the dummy substrates, is approximately the same value in each process chamber, per one processing in the process chamber.

Preferably, when the number of the dummy substrates is decided so that the number of substrates in each process chamber reaches the prescribed number in performing lot processing by distributing each type of the substrates to each process chamber, the controller performs control to decide the number of the dummy substrates so that a value obtained by dividing a cumulative integrated value of a deposited film formed on the dummy substrates by a cumulative number of the dummy substrates used in each process chamber, is approximately the same value in each process chamber in each lot processing per one processing in each process chamber.

Preferably, when the number of the dummy substrates is decided so that the number of substrates in each process chamber reaches the prescribed number in performing lot processing by distributing each type of the substrates to each process chamber, the controller is configured to perform control to decide the number of the dummy substrates so that a cumulative value of values obtained by integrating a deposited film formed in the process chamber by the number of the dummy substrates used in the process chamber, is approximately the same value in each process chamber in each lot processing per one processing in the process chamber.

Further preferably, there is provided a substrate processing apparatus, wherein when distributing each type of the substrates to each process chamber and applying multiple numbers of times of processing to each type of the substrates respectively, the controller is configured to perform control to compare film thickness values of the dummy substrates in each process chamber in at least previous processing, and transfer the dummy substrates to a process chamber with a small film thickness value.

Further preferably, when each type of the substrates is distributed to each process chamber and lot processing is applied thereto continuously, the controller performs control so that total values of cumulative film thickness values of the dummy substrates are compared when starting the lot processing, and as a result, the dummy substrates are distributed to a process chamber with a small total value of cumulative film thickness values, so that the dummy substrates are equally used in each process chamber until an end of the lot processing.

Further preferably, when each type of the substrates is distributed to each process chamber and lot processing is applied thereto continuously, the controller performs control so that total values of cumulative film thickness values of cumulative film thickness values of the dummy substrates are compared in each process chamber when starting the lot processing or while processing each lot, and as a result, the dummy substrates are transferred to a process chamber with a small total value of cumulative film thickness values so that the dummy substrates are equally used in each process chamber until an end of the lot processing.

According to other aspect of the present invention, there is provided a substrate processing apparatus, including:

a plurality of process chambers configured to process a plurality of product substrates; and

a controller configured to perform control to collectively process lots of the product substrates in one process chamber even in a case of a different lot, when performing lot processing by distributing the product substrates to each process chamber.

According to further other aspect of the present invention, there is provided a method for processing substrates in a substrate processing apparatus including at least one process chamber in which a plurality of product substrates are processed, including:

loading into the same process chamber a product substrate of a next lot when the number of substrates does not reach a processable number in the process chamber when a last product substrate of a prescribed lot is disposed at a prescribed position in the process chamber, to refill the process chamber; and

collectively processing the plurality of product substrates in the same process chamber.

Preferably, a sequence recipe of each lot is the same.

According to further other aspect of the present invention, there is provided a substrate processing apparatus, including:

a substrate storage unit exclusive for separately storing a plurality of dummy substrates and a plurality of product substrates respectively;

a process chamber in which a plurality of substrates composed of at least either the dummy substrates or the product substrates are processed; and

a controller configured to perform control to distribute the dummy substrates in the substrate storage unit to each process chamber and process the plurality of substrates in the process chamber, so that the dummy substrates are equally processed as much as possible.

Preferably, the number of the dummy substrates distributed to each prescribed process chamber, is decided so that a value obtained by dividing an average film thickness value of a deposited film formed in the prescribed process chamber per one processing in the prescribed process chamber, by the number of the dummy substrates distributed to each prescribed process chamber, is approximately the same value in each process chamber.

Further preferably, when the product substrates and the dummy substrates are combined, the product substrates designated by a different job having the same sequence recipe, are combined, to decide the product substrates processed simultaneously in the process chamber.

Further preferably, when the product substrates and the dummy substrates are combined, the product substrates and the dummy substrates are combined for each group unit having the same jobs for executing a plurality of jobs having different sequence recipes, to perform parallel processing in the plurality of process chambers for each group unit.

According to further other aspect of the present invention, there is provided a substrate processing apparatus, including:

a plurality of process chambers in which a plurality of substrates including product substrates and dummy substrates are simultaneously processed,

wherein the dummy substrates are distributed to each process chamber, and

the product substrates and the dummy substrates processed simultaneously in the process chambers, are decided so that the dummy substrates distributed to each process chamber are equally used as much as possible.

Preferably, when the dummy substrates are distributed, the number of the dummy substrates to be distributed is decided in each process chamber so that a value obtained by dividing an average film thickness value of a deposited film formed in a prescribed process chamber per one processing, by the number of the dummy substrates distributed to the prescribed process chamber, is approximately the same value in each process chamber.

Further preferably, when the product substrates and the dummy substrates are combined, the product substrates designated by different jobs having the same sequence recipe are combined, to decide the product substrates processed simultaneously in the process chamber.

Further preferably, when the product substrates and the dummy substrates are combined, the product substrates and the dummy substrates are combined for each group unit having the same jobs for executing a plurality of jobs having different sequence recipes, to perform parallel processing in the plurality of process chambers for each group unit.

According to further other aspect of the present invention, there is provided an operation method of dummy substrates in a substrate processing apparatus including a plurality of process chambers in which a plurality of substrates are processed, including distributing the number of the dummy substrates to be used to each process chamber, and combining product substrates and the dummy substrates to be the plurality of substrates so that the dummy substrates are equally used as much as possible.

According to further other aspect of the present invention, there is provided a method for processing substrates in a substrate processing apparatus including a plurality of process chambers in which a plurality of product substrates are processed, including:

collectively processing lots of the product substrates in one process chamber even in a case of a different lot, when the product substrate are distributed to each process chamber and lot processing is repeatedly applied thereto.

According to further other aspect of the present invention, there is provided a method for processing substrates in a substrate processing apparatus including at least one process chamber in which a plurality of product substrates are processed, including:

loading into the same process chamber a last product substrate of a prescribed lot when the number of substrates does not reach a processable number in the process chamber when a last product substrate of a prescribed lot is disposed at a prescribed position in the process chamber, to refill the process chamber; and

collectively processing the plurality of product substrates in the same process chamber.

According to further other aspect of the present invention, there is provided an operation method of dummy substrates in a substrate processing apparatus including a substrate storage unit exclusive for separately storing a plurality of dummy substrates and a plurality of product substrates respectively; and a process chamber in which a plurality of substrates composed of at least either the dummy substrates or the product substrates are processed, the operation method including:

distributing the dummy substrates in the substrate storage unit to each process chamber, so that the dummy substrates are equally used as much as possible; and

processing the plurality of substrates in the process chamber.

According to further other aspect of the present invention, there is provided a substrate transfer method, including:

deciding the number of dummy substrates used in each process chamber so that the number of substrates in each process chamber reaches a prescribed number; and

transferring each type of substrates including the dummy substrates,

wherein when deciding the number of the dummy substrates, the number of the dummy substrates is decided so that the number of the dummy substrates used in each process chamber is approximately the same in each process chamber.

According to further other aspect of the present invention, there is provided a substrate transfer method including:

deciding the number of dummy substrates used in each process chamber so that the number of substrates in each process chamber reaches a prescribed number; and

transferring each type of substrates including the dummy substrates to the process chamber so that the number of substrates reaches the prescribed number,

wherein when deciding the number, total values of cumulative film thickness values of the dummy substrates are compared in each process chamber, and as a result, the dummy substrates are distributed to a process chamber with a small total value of cumulative film thickness values.

According to further other aspect of the present invention, there is provided a method for manufacturing a semiconductor device, including:

deciding the number of dummy substrates used in each process chamber so that the number of substrates in each process chamber reaches a prescribed number;

transferring each type of substrates including the dummy substrates; and

distributing and processing each type of the substrates to/in the process chamber.

wherein when deciding the number of the dummy substrates, the number of the dummy substrates is decided so that the number of the dummy substrates used in each process chamber is approximately the same in each process chamber.

According to further other aspect of the present invention, there is provided a method for manufacturing a semiconductor device, including:

deciding the number of dummy substrates used in each process chamber so that the number of substrates in each process chamber reaches a prescribed number;

transferring each type of substrates including the dummy substrates so that the number of the substrates in the process chamber reaches the prescribed number; and

processing the prescribed number of the substrates,

wherein when each type of the substrates are distributed to each process chamber and lot processing is applied thereto continuously, when deciding the number, total values of cumulative film thickness values of the dummy substrates are compared in each process chamber when starting the lot processing, and as a result, the dummy substrates are distributed to a process chamber with a small total value of cumulative film thickness values.

What is claimed is:

1. A substrate processing apparatus, comprising:
a plurality of process chambers in which a prescribed number of each type of substrates is processed; and
a controller configured to decide the number of dummy substrates so that the number of the dummy substrates used in each process chamber is approximately the same between the process chambers, when the number of the dummy substrates used in each process chamber is decided so that the number of each type of substrates used in each process chamber reaches the prescribed number.

2. A substrate transfer method, comprising:
deciding the number of dummy substrates used in each process chamber, so that the number of each type of substrates in each process chamber reaches a prescribed number; and
transferring each type of the substrates,
when deciding the number of the dummy substrates, the number of the dummy substrates is decided so that the number of the dummy substrates used in each process chamber is approximately the same in each process chamber.

3. A method for manufacturing a semiconductor device, comprising:
deciding the number of dummy substrates used in each process chamber, so that the number of each type of substrates in each process chamber reaches a prescribed number;
transferring each type of the substrates; and
processing each type of the substrates in each process chamber,
when deciding the number of the dummy substrates, the number of the dummy substrates is decided so that the number of the dummy substrates used in each process chamber is approximately the same in each process chamber.

4. A substrate processing apparatus, comprising:
a plurality of process chambers in which a prescribed number of each type of substrates are processed; and
a controller configured to decide the number of dummy substrates used in each process chamber so that the number of each type of the substrates reaches the prescribed number in each process chamber,
the controller being configured to further perform control to compare film thickness values of a deposited film on the dummy substrates in each process chamber in at least previous processing, and transfer the dummy substrates into a process chamber in which a film thickness value is small when each type of the substrates is distributed to each process chamber and multiple numbers of times of processing are applied to each type of the substrates.

5. The substrate processing apparatus according to claim 1, wherein the controller is configured to further perform control such that the number of the dummy substrates is decided so that the number of the dummy substrates used in last processing in each process chamber, is approximately the same number in each process chamber.

6. The substrate processing apparatus according to claim 1, wherein the controller is configured to further perform control so that a value obtained by dividing an integrated film thickness value of a deposited film formed on the dummy substrates in last processing in each process chamber, by the number of the dummy substrates, is approximately the same value in each process chamber.

7. The substrate processing apparatus according to claim 1, wherein the controller is configured to further perform control to decide the number of the dummy substrates so that a value obtained by integrating a film thickness values of a deposited film formed in the process chamber in last processing in each process chamber, by the number of the dummy substrates used in the process chamber, is approximately the same value in each process chamber.

8. The substrate processing apparatus according to claim 1, wherein the controller is configured to further perform control to decide the number of the dummy substrates so that a cumulative value of values obtained by integrating film thickness values of a deposited film formed on the dummy substrates by the number of the dummy substrates used in the process chamber, is approximately the same value between the process chambers in each lot processing in distributing each type of the substrates to each process chamber and deciding the number of the dummy substrates so that the number of each type of the substrates reaches the prescribed number in each process chamber.

9. The substrate processing apparatus according to claim 1, wherein the controller is configured to further perform control to decide the number of the dummy substrates so that a cumulative value of values obtained by integrating film thickness values of a deposited film formed in the process chamber by the number of the dummy substrates used in the process chamber, is approximately the same value between the process chambers in each lot processing in distributing each type of the substrates to each process chamber and deciding the number of the dummy substrates so that the number of each type of the substrates reaches the prescribed number in each process chamber.

10. The substrate processing apparatus according to claim 4, wherein the controller is configured to further perform control to compare total values of film thickness values of a deposited film on the dummy substrates in each process chamber before starting each processing, and transfer the dummy substrates into a process chamber with a small total value of cumulative film thickness values in distributing each type of the substrates to each process chamber and applying multiple numbers of times of processing to each type of the substrates respectively.
